(19) United States
(12) Patent Application Publication
(10) Pub. No.: US 2023/0387137 A1
(43) Pub. Date: Nov. 30, 2023

(54) THIN FILM TRANSISTOR, DISPLAY DEVICE, AND METHOD FOR MANUFACTURING THIN FILM TRANSISTOR

(71) Applicant: JAPAN SCIENCE AND TECHNOLOGY AGENCY, Saitama (JP)

(72) Inventors: Hideo HOSONO, Kanagawa (JP); Junghwan Kim, Kanagawa (JP); Hideya Kumomi, Kanagawa (JP)

(21) Appl. No.: 18/233,414

(22) Filed: Aug. 14, 2023

Related U.S. Application Data
(63) Continuation of application No. PCT/JP2022/006733, filed on Feb. 18, 2022.

(30) Foreign Application Priority Data
Feb. 22, 2021 (JP) 2021-026653
Oct. 25, 2021 (JP) 2021-174071

(51) Int. Cl. H01L 27/12

(52) U.S. Cl. CPC H01L 27/1225; H01L 27/127; H10K 59/1201

(57) ABSTRACT

In an embodiment, a thin film transistor is formed on a substrate, the thin film transistor includes a channel formed by at least part of a metal oxide semiconductor layer containing at least indium (In), a gate electrode, a gate insulating layer arranged between the channel and the gate electrode, a source electrode connected to the metal oxide semiconductor layer, and a drain electrode connected to the metal oxide semiconductor layer. For example, the average concentration of carbon atoms in an area from a surface to the depth of 5 nm of the channel is 1.5×10²¹ cm⁻³ or less, whereby a threshold shift due to a voltage stress can be effectively reduced.

### CROSS REFERENCE TO RELATED APPLICATIONS

This application is a Continuation of International Patent Application No. PCT/JP2022/006733, filed on Feb. 18, 2022, which claims the benefit of priority to Japanese Patent Application No. 2021-026653, filed on Feb. 22, 2021 and Japanese Patent Application No. 2021-174071, filed on Oct. 25, 2021, the entire contents of which are incorporated herein by reference.

### FIELD

The present invention relates to a thin film transistor containing a metal oxide semiconductor.

### BACKGROUND

A thin film transistor containing a metal oxide semiconductor exemplified by InGaZnO (hereinafter referred to as IGZO) is used as an element for driving pixels of a display. A thin film transistor containing IGZO with a composition ratio of In and Ga of 1:1 has a mobility of about 10 cm²/Vs. Although this mobility is higher than a mobility of a thin film transistor containing an amorphous silicon, it is lower than a mobility of a thin film transistor containing a low-temperature polysilicon.

In recent years, with the increase in the number of pixels and size of a display represented by 4K and 8K resolution display, IGZO capable of manufacturing a thin film transistor having higher mobility than an amorphous silicon and superior uniformity in a large area than a low-temperature polysilicon has been adopted. For example, in order to improve the mobility of IGZO, a thin film transistor containing IGZO in which In is richer than 1:1 in the composition ratio of In and Ga has been developed. In addition, a thin film transistor containing a metal oxide semiconductor that enables higher mobility than IGZO are being developed for next-generation displays. As one of them, a thin film transistor using InSnZnO (hereinafter referred to as ITZO) can achieve a mobility of about 50 cm²/Vs. Therefore, a thin film transistor used in a circuit requiring high mobility can be replaced with ITZO from a low-temperature polysilicon. On the other hand, an n-type thin film transistor containing ITZO has a disadvantage that a negative shift occurs in a threshold voltage due to NBTS (Negative Bias Temperature Stress). Hereinafter, the threshold voltage is sometimes simply referred to as a threshold. A threshold before stress application is shown as Vth, and the amount of the shift obtained by subtracting the threshold before stress application from a threshold after stress application is shown as ΔVth. In addition, the threshold is also used in the case of NBIS and PBTS. In the n-type thin film transistor, the negative shift of the threshold due to an application of a continuous negative-bias voltage means that the transistor that should be initially controlled to an off state by the application of the negative-bias voltage is turned on by itself over time, and thus the amount of the negative shift needs to be sufficiently reduced.

For example, Non-Patent Literature 1 (W. -H, Tseng et. al., Solid-State Electronics 103 (2015), 173-177) discloses that, as a way to solve this problem, an N₂O plasma treatment on a backchannel side of ITZO is performed at appropriate times for defects caused by C═O and C—O coupling or the like that deteriorate properties of the thin film transistor.

According to FIG. 6 of Non-Patent Literature 1, it can be understood that, in a ITZO thin film transistor, a negative shift of a threshold due to the NBTS decreases as a duration of the N₂O plasma treatment increases, but the negative shift increases if the processing time exceeds an optimum value. That is, in order to reduce the negative shift of the threshold in accordance with the process described in Non-Patent Literature 1, it is considered that it is necessary to grasp a surface condition of a backchannel of ITZO and precisely control the duration of the N₂O plasma treatment in accordance with the surface condition. Even when passivation layers are formed by a PECVD (Plasma Enhanced Chemical Vapor Deposition) method after the N₂O plasma treatment, it becomes more difficult to control the duration due to exposure to the N₂O plasma. As a result, a requirement of such control can also cause manufacturing variations. Therefore, it is desired to reduce the negative shift of the threshold by a method different from the N₂O plasma treatment.

### SUMMARY

A thin film transistor according to an embodiment is a thin film transistor formed on a substrate, the thin film transistor includes a channel formed by at least part of a metal oxide semiconductor layer containing Indium (In), a gate electrode, a gate insulating layer arranged between the channel and the gate electrode, and a source electrode and a drain electrode connected to the metal oxide semiconductor layer. The average concentration of carbon atoms in an area from a surface to a depth of 5 nm of the channel may be 1.5×10²¹ cm⁻³ or less. The maximum concentration of carbon atoms in the area from the surface to the depth 5 nm of the channel may be 19 at % or less. The electron affinity of a passivation layer having an insulating property and covering the channel may be smaller than the electron affinity of the metal oxide semiconductor layer.

### BRIEF DESCRIPTION OF DRAWINGS

FIG. 1 is a diagram showing a display device according to an embodiment.

FIG. 2 is a diagram schematically showing a cross-sectional structure of a pixel according to an embodiment.

FIG. 3 is a diagram for explaining a method for manufacturing a display device according to an embodiment.

FIG. 4 is a diagram for explaining a method for manufacturing a display device according to an embodiment.

FIG. 5 is a diagram for explaining a method for manufacturing a display device according to an embodiment.

FIG. 6 is a diagram showing a thin film transistor according to an embodiment.

FIG. 7 is a diagram for explaining a method for manufacturing a display device according to an embodiment.

FIG. 8 is a diagram for explaining a method for manufacturing a display device according to an embodiment.

FIG. 9 is a diagram showing a thin film transistor for threshold shift measurement.

FIG. 10 is a diagram for explaining a method for manufacturing a thin film transistor for measurement.

FIG. 11 is a diagram for explaining a method for manufacturing a thin film transistor for measurement.

FIG. 12 is a diagram for explaining a method for manufacturing a thin film transistor for measurement.

FIG. 13 is a graph showing TDS measurement results before photoresist formation and after photoresist formation/removal.

FIG. 14 is a graph showing HAX-PES measurement results (C1s) before photoresist formation and after photoresist formation/removal.

FIG. 15 is a graph showing HAX-PES measurement results (O1s) before photoresist formation and after photoresist formation/removal.

FIG. 16 is a graph showing TDS measurement results according to the heating temperature.

FIG. 17 is a graph showing measurement results of an Auger electron spectroscopy for an After PR sample and a sample after a heat treatment.

FIG. 18 is a graph showing measurement results of a threshold shift due to NBTS.

FIG. 19 is a graph showing measurement results of a threshold shift due to NBIS.

FIG. 20 is a graph showing the TDS measurement results after photoresist formation/removal and after a UV ozone treatment.

FIG. 21 is a graph showing measurement results of a threshold shift due to NBTS and PBTS after a UV ozone treatment.

FIG. 22 is a diagram showing an ESL thin film transistor according to an embodiment.

FIG. 23 is a diagram showing a top gate-type thin film transistor according to an embodiment.

FIG. 24 is a diagram showing an electronic appliance according to an embodiment.

FIG. 25 is a diagram showing a thin film transistor including a passivation layer according to an embodiment.

FIG. 26 is a diagram showing a thin film transistor including a passivation layer according to an embodiment.

FIG. 27 is a diagram showing a thin film transistor including a passivation layer according to an embodiment.

FIG. 28 is a graph showing measurement results of a threshold shift according to a temperature change in presence or absence of a-ZSO passivation layer.

FIG. 29 is a graph showing measurement results of a threshold shift due to NBIS in presence or absence of a-ZSO passivation layer.

FIG. 30 is a graph showing measurement results of electron concentrations before and after a light irradiation in presence or absence of a-ZSO passivation layer.

FIG. 31 is a graph showing measurement results of an absorption coefficient in presence or absence of a-ZSO passivation layer.

FIG. 32 is a graph showing measurement results of a variation of a threshold shift over time due to NBS and a modeling formula.

FIG. 33 is a graph showing measurement results of a threshold shift due to NBTS and PBTS.

FIG. 34 is a graph showing measurement results of a threshold shift due to NBTS and PBTS.

FIG. 35 is a graph showing measurement results of a threshold shift due to NBTS.

FIG. 36 is a diagram showing a top gate-type thin film transistor including a passivation layer according to an embodiment.

FIG. 37 is a diagram showing a top gate-type thin film transistor including a passivation layer according to an embodiment.

FIG. 38 is a graph showing measurement results of a threshold shift (ITGO) due to NBS in presence or absence of a UV ozone treatment.

FIG. 39 is a graph showing measurement results of a threshold shift (IZO) due to NBS in presence or absence of a UV ozone treatment.

### DESCRIPTION OF EMBODIMENTS

Hereinafter, an embodiment of the present invention will be described in detail with reference to the drawings. The following embodiments are examples, and the present invention should not be construed as being limited to these embodiments. In the drawings referred to in the present embodiment, the same or similar parts are denoted by the same reference sign or similar reference sign (only denoted by A, B, and the like after a numeral), and repetitive description thereof may be omitted. In the drawings, dimensional ratios may be different from actual ratios, or part of the configuration may be omitted from the drawings for clarity of explanation.

In describing a positional relationship of a second component with respect to a first component, expressions “above”/“over” and “below”/“under” are not limited to the case where the second component is in contact with the first component above or below, and includes cases where still other configurations are interposed unless otherwise specified.

### Overview

In this example, a display device in an embodiment is an organic EL (Electro Luminescence) display using an OLED (Organic Light Emitting Diode). The organic EL display may enable color display by using a plurality of OLEDs that emit light of different colors, or may enable color display by using the OLED that emits white light and color filters. The display device may further have a function of a touch sensor. The touch sensor detects contacts of a finger, a stylus, or the like on the display surface by, for example, a self-capacitance method or a mutual capacitance method.

The display device includes a thin film transistor containing ITZO. According to a driving method of the display device, the thin film transistor spends much time controlled in an off state. Therefore, it is not desirable to use a thin film transistor in which a negative shift of a threshold due to NBTS is likely to occur. As described in detail below, according to the thin film transistor containing ITZO, it has been achieved that the negative shift of the threshold due to the NBTS is reduced by methods based on findings obtained by the inventors.

First, a configuration of the display device will be described, and a configuration of the thin film transistor included in the display device and a configuration for achieving the reduction of the negative shift of the threshold due to the NBTS will be described later.

[Configuration of Display Device]

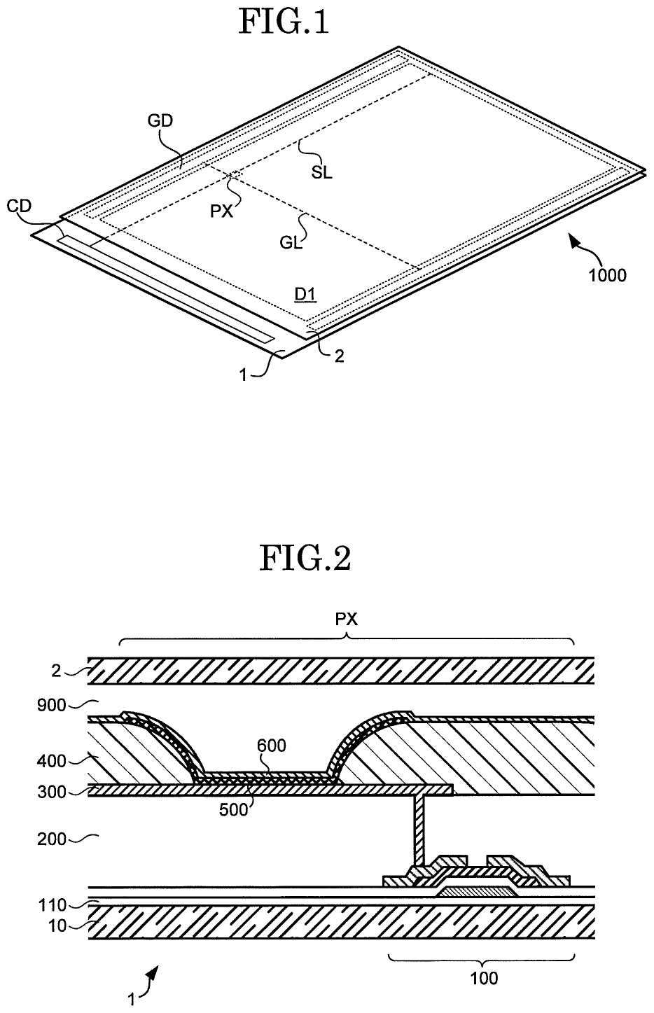

FIG. 1 is a diagram showing a display device according to an embodiment. A display device 1000 has a structure in which a first substrate 1 and a second substrate 2 are bonded together by a bonding material. The first substrate 1 includes a display area D1 and a drive circuit GD. A driver IC (Integrated Circuit) chip CD is mounted on the first substrate 1. The driver IC chip CD may be mounted on FPCs (Flexible Printed Circuits) connected to the first substrate 1. In FIG. 1, the FPCs are omitted. The second substrate 2 protects elements formed on the first substrate 1. Instead of the second substrate 2, a cover layer covering elements formed on the first substrate 1 may be arranged.

In the display area D1, a plurality of scan signal lines GL, a plurality of data signal lines SL, and a plurality of pixels PX are arranged. For example, the plurality of pixels PX are arranged in a matrix. The scan signal line GL and the data signal line SL are arranged so as to intersect with each other. The pixels PX are arranged at a part where the scan signal line GL and the data signal line SL intersect with each other. In FIG. 1, although one scan signal line GL and one data signal line SL are arranged with respect to one pixel PX, another signal line may also be arranged.

The drive circuit GD is arranged adjacent to the display area D1 and is connected to the scan signal line GL. The driver IC chip CD is connected to the data signal line SL and the drive circuit GD. The driver IC chip CD controls a signal to be supplied to the data signal line SL based on an external control signal, and further controls the drive circuit GD to control a signal to be supplied to the scan signal line GL. In this example, the drive circuit GD includes a circuit such as a shift register using a thin film transistor 100 (see FIG. 2). Since the thin film transistor 100 is an n-type transistor, a bootstrap circuit may be used to enable a circuit configuration included in the drive circuit GD.

The pixel PX includes a light emitting element that is an OLED, and a pixel circuit for controlling light emission by the light emitting element. The pixel circuit includes elements such as the thin film transistor 100 and a capacitor. In this embodiment, the pixel circuit included in one pixel PX has a plurality of thin film transistors 100. In this example, light emitted from the light emitting element travels in a direction opposite to the first substrate 1 on which the light emitting element is formed, and is visually recognized by a user through the second substrate 2. That is, a top emission type is applied to the display device 1000. A bottom emission type may be applied to the display device 1000.

FIG. 2 is a diagram schematically showing a cross-sectional structure of a pixel according to an embodiment. The first substrate 1 includes a first supporting substrate 10, a base insulating layer 110, the thin film transistor 100, an interlayer insulating layer 200, a pixel electrode 300, a bank layer 400, a light emitting layer 500, a counter electrode 600, and a sealing layer 900. The second substrate 2 is arranged so as to cover the sealing layer 900. As described above, although the plurality of thin film transistors 100 are used in one pixel circuit, in FIG. 2, one thin film transistor 100 connected to the pixel electrode 300 is shown, and an illustration of the other thin film transistors 100 is omitted.

The first supporting substrate 10 and the second substrate 2 are glass substrates. One or both of the first supporting substrate 10 and the second substrate 2 may be a flexible substrate such as an organic resin substrate.

The base insulating layer 110 is arranged on the first supporting substrate 10, and prevents intrusions of moisture and gas into the inside. The base insulating layer 110 includes, for example, an insulating film such as silicon oxide or silicon nitride. The base insulating layer 110 may include a structure in which multiple types of insulating films are stacked.

As described above, the thin film transistor 100 contains ITZO as a semiconductor layer and is arranged on the base insulating layer 110. In this example, the thin film transistor 100 is a thin film transistor of a BCE (Back Channel Etch) type. A detailed configuration of the thin film transistor 100 will be described later.

The interlayer insulating layer 200 covers the thin film transistor 100. The interlayer insulating layer 200 includes, for example, an inorganic insulating film such as silicon oxide or silicon nitride. The interlayer insulating layer 200 may include a structure in which multiple types of insulating films are stacked. In this example, a silicon oxide film of the interlayer insulating layer 200 is in contact with the thin film transistor 100. The interlayer insulating layer 200 may further include a planarization insulating film on the inorganic insulating film. The planarization insulating film may be an organic insulating film such as acrylic, polyimide, or epoxy resin. In the case where the interlayer insulating layer 200 includes a structure in which a plurality of insulating films are stacked, a conductive film used for wirings and the like may be arranged between the plurality of insulating films.

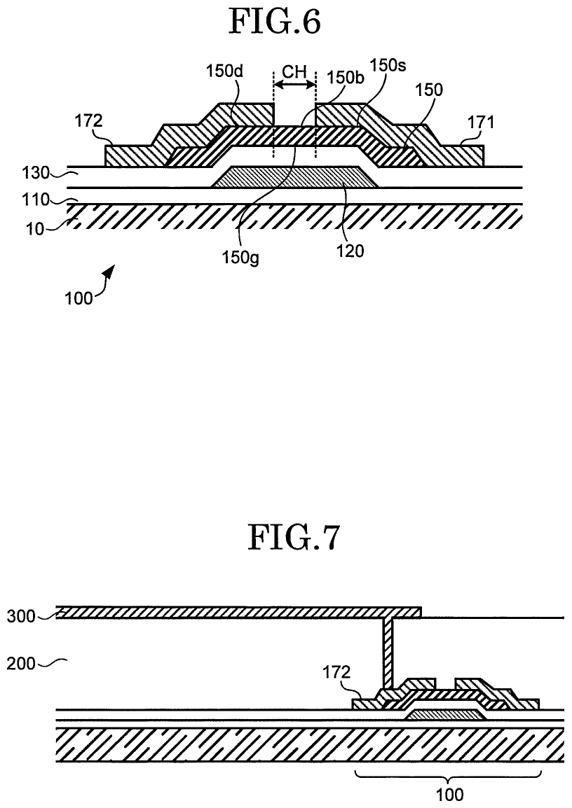

The pixel electrode 300 is connected to a drain electrode 172 (see FIG. 6) of the thin film transistor 100 via a contact hole formed in the interlayer insulating layer 200. The pixel electrode 300 includes a conductive film that functions as a cathode of the light emitting layer 500. The pixel electrode 300 includes a stacked structure of one type of conductive film or multiple types of conductive films. Depending on the configuration of the pixel circuit, the pixel electrode 300 may function as an anode of the light emitting layer 500. In this case, the pixel electrode 300 is connected to a source electrode 171 of the thin film transistor 100. As described above, since the top emission type is applied to the display device 1000, the pixel electrode 300 does not have to have light transmittance. In the case where the bottom emission type is applied to the display device 1000, the pixel electrode has light transmittance.

The bank layer 400 covers an end portion of the pixel electrode 300 and includes an opening portion that exposes part of the pixel electrode 300. The bank layer 400 includes, for example, an organic insulating film such as acrylic, polyimide, or epoxy resin.

The light emitting layer 500 is arranged so as to cover part of the pixel electrode 300 and the bank layer 400. The light emitting layer 500 has a structure in which multiple types of organic materials are stacked. The light emitting layer 500 emits light by a current being supplied. By changing at least one of the plurality of organic materials constituting the light emitting layer 500, emission colors can be made different from each other.

The counter electrode 600 covers the light emitting layer 500. The counter electrode 600 includes a conductive film that functions as an anode of the light emitting layer 500. The counter electrode 600 includes a stacked structure of one type of conductive film or multiple types of conductive films. As described above, depending on the configuration of the pixel circuit, the counter electrode 600 may function as a cathode of the light emitting layer 500. As described above, since the top emission type is applied to the display device 1000, the counter electrode 600 has light transmittance. The pixel electrode 300, the light emitting layer 500, and the counter electrode 600 form light emitting elements in each of the pixels PX.

The sealing layer 900 is an insulating layer that covers the entire display area D1 and prevents intrusions of moisture and gases into the light emitting layer 500. The sealing layer 900 includes, for example, a structure in which a silicon nitride film arranged on the counter electrode 600 and a planarization insulating film on the silicon nitride film are stacked, and has light transmittance. The planarization insulating film may be, for example, an organic insulating film such as acrylic, polyimide, or epoxy resin. The sealing layer 900 may be arranged so as to be sandwiched between the silicon nitride film and the second substrate 2 and function as a member for bonding the first substrate 1 and the second substrate 2.

[Method for Manufacturing Display Device]

Next, a method for manufacturing the display device 1000 will be described.

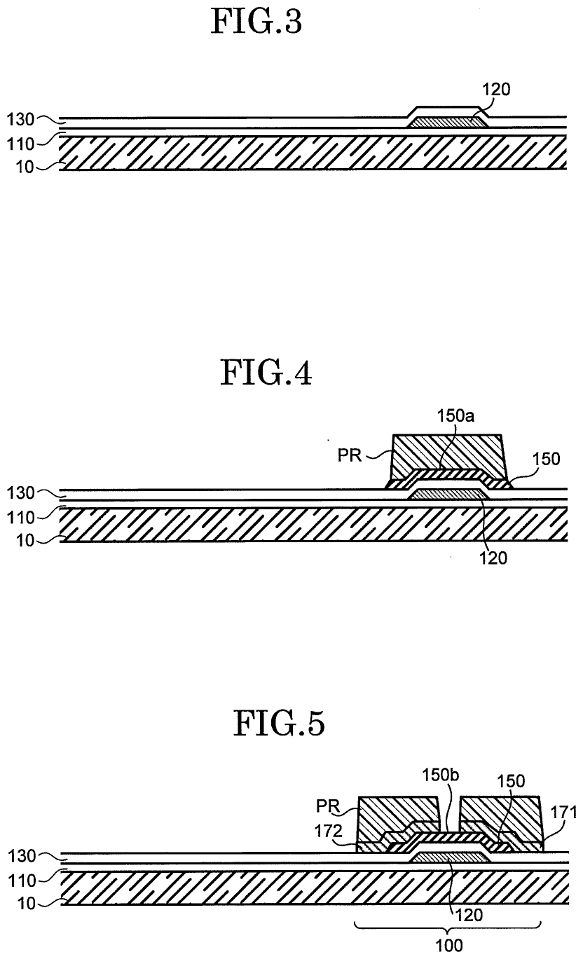

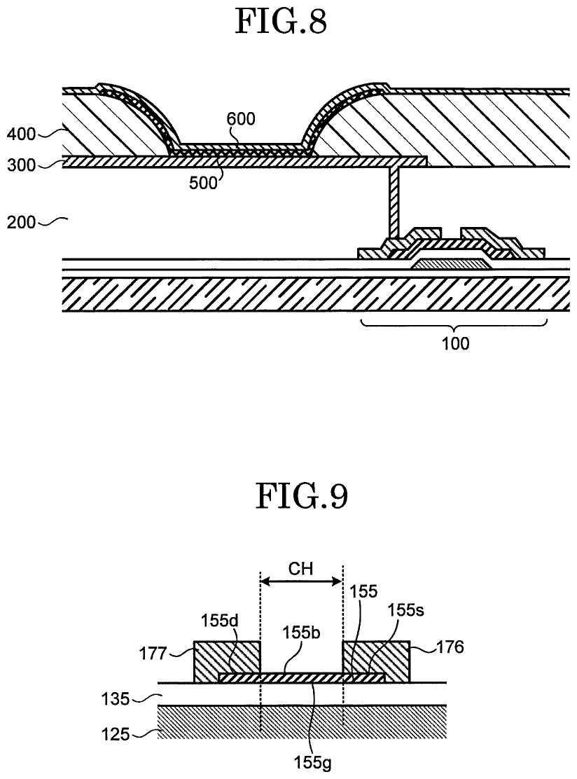

FIG. 3 to FIG. 5, FIG. 7, and FIG. 8 are diagrams for explaining a method for manufacturing the display device 1000 according to an embodiment. In particular, in FIG. 3 to FIG. 5, a method for manufacturing the thin film transistor 100 in the display device 1000 will be described. First, the first supporting substrate 10 is prepared, and the base insulating layer 110 is formed on the first supporting substrate 10. The base insulating layer 110 is formed by, for example, a CVD (Chemical Vapor Deposition) method or a PVD (Physical Vapor Deposition) method. The CVD method includes, for example, the PECVD method. The PVD method includes a sputtering method. The same applies to the following description.

A gate electrode 120 is obtained by forming a film of a conductive material formed by the PVD method on the base insulating layer 110 in a desired pattern. The desired pattern is formed by, for example, an etching process or a lift-off process using a photoresist by photolithography. The gate electrode 120 may be formed in a patterned state by a printing method, an ink jet method, or the like. When the gate electrode 120 is formed, at least one of the scan signal line GL and the data signal line SL may be formed at the same time. The conductive material is, for example, a metal such as molybdenum, tantalum, tungsten, gold, copper, chromium, aluminum, or a metal compound containing at least one of these metals. The gate electrode 120 may include a structure in which multiple types of conductive materials are stacked. In this example, the gate electrode 120 includes a structure in which molybdenum and copper are stacked in this order from the first supporting substrate 10 side.

A gate insulating layer 130 is formed to cover the gate electrode 120 and the base insulating layer 110 by the CVD method or the PVD method. Although a thickness of the gate insulating layer 130 may vary, for example, 20 nm or more and 200 nm or less is preferable, and 50 nm or more and 150 nm or less is more preferable. A configuration after the gate insulating layer 130 is formed corresponds to FIG. 3. The gate insulating layer 130 is formed of an inorganic insulating material. The inorganic insulating material is, for example, silicon nitride, silicon oxide, silicon oxynitride, aluminum oxide, hafnium oxide, and the like. The gate insulating layer 130 may include a structure in which multiple types of inorganic insulating materials are stacked. In this example, the gate insulating layer 130 includes a structure in which the silicon nitride film and the silicon oxide film are stacked in this order from the gate electrode 120 side.

Subsequently, an ITZO film is formed on the gate insulating layer 130 by the CVD method or the PVD method. In this case, ITZO is formed by the sputtering method using gas containing argon and oxygen. In this example, the ITZO film is amorphous, but may contain microcrystals. Elements other than In, Sn, Zn and O may be contained. In an area from a surface to a depth of 5 nm of a channel CH (see FIG. 6), a portion having 10 at % or more of Sn may be contained, and a portion having 13 at % or more of Sn may be contained. In the area from the surface to the depth of 5 nm of channel CH, a portion in which an atomic percent of Sn is greater than an atomic percent of Zn may be contained. Although a thickness of the ITZO film may be varied, for example, 10 nm or more and 200 nm or less is preferable, and 20 nm or more and 100 nm or less is more preferable. A semiconductor layer 150 is obtained by forming the ITZO film in a desired pattern. The desired pattern is formed by, for example, the etching process or the lift-off process using the photoresist by photolithography. A configuration after a photoresist PR is formed on the ITZO film and the island-shaped semiconductor layer 150 are formed by the etching process corresponds to FIG. 4. The example shown in FIG. 4 is a state prior to removing the photoresist PR.

When photolithography is performed, an upper surface 150a of the semiconducting layers 150 contacts the photoresist PR. As will be described later, when the photoresist PR comes into contact with the semiconductor layer 150 which is the ITZO film, the carbon atoms “C” which are organic compounds contained in the photoresist PR are bound to the contact surface (upper surface 150a). Even if the upper surface 150a of the semiconductor layer 150 is exposed to an etchant (hereinafter referred to as a stripping solution) for removing the photoresist PR, the carbon atoms bound to the upper surface 150a are not removed.

The carbon atoms remain as “C—O” and “C═O” (hereinafter referred to as carbon residual components). It is said that ITZO has the surface on which “C—O” and “C═O” are easily adsorbed due to having SnOₓ (tin oxide). It is said that In₂Oₓ (indium oxide) and ZnOₓ (zinc oxide) have the same tendency as SnOₓ (tin oxide), although their impacts are small. The carbon residual components introduce defects into ITZO. In ITZO, electrons are supplied by the carbon residual components to increase an electron density, and holes are trapped in the defects due to the NBTS, which are considered to cause the thresholds to shift to negative.

In the case where the semiconductor layer 150 is formed by the lift-off process, although the upper surface 150a of the semiconductor layer 150 is not contacted by the photoresist PR, there is a possibility that a carbon residual component may similarly be generated on the upper surface 150a due to an effect of organic compounds contained in the stripping solution and components of the dissolved photoresist PR by being exposed by the stripping solution when removing the photoresist PR for lift-off.

The source electrode 171 and the drain electrode 172 are formed by forming films of conductive materials formed on the semiconductor layer 150 and the gate insulating layer 130 in desired patterns by the PVD method. The desired patterns are formed by, for example, the etching process or the lift-off process using the photoresist by photolithography. When the source electrode 171 and the drain electrode 172 are formed, at least one of the scan signal line GL and the data signal line SL may be formed at the same time. The conductive material is, for example, a metal such as molybdenum, tantalum, tungsten, gold, copper, chromium, aluminum, or a metal compound containing at least one of these metals.

The source electrode 171 and the drain electrode 172 are preferably made of a conductive material having oxidation resistance. The source electrode 171 and the drain electrode 172 may include a structure in which multiple types of conductive materials are stacked. In this case, it is preferable that at least the conductive material exposed on the upper surface has oxidation resistance. In this example, the source electrode 171 and the drain electrode 172 include a structure in which molybdenum and copper are stacked in this order from the semiconductor layer 150 side.

A configuration after the source electrode 171 and the drain electrode 172 are formed by the etching process in which the photoresist PR is formed on the conductive material corresponds to FIG. 5. The example shown in FIG. 5 is a state prior to removing the photoresist PR. In this state, although a backchannel side surface 150b of the semiconductor layer 150 is not contacted with the photoresist PR, carbon residual components may likewise form on the backchannel-side surface 150b by being exposed by the stripping solution for removing the photoresist PR when removing the photoresist PR.

Depending on the etchant used to form the source electrode 171 and the drain electrode 172, the backchannel-side surface 150b may contain the carbon residual components. For example, in a PAN etchant including phosphoric acid, nitric acid, and acetic acid, acetic acid may cause the carbon residual components to be generated. At least the backchannel-side surface 150b contacts the photoresist PR in a state shown in FIG. 4. Therefore, there is a possibility that the carbon residual components remain in the backchannel-side surface 150b as they are.

In the case where the source electrode 171 and the drain electrode 172 are formed by the lift-off process, the carbon residual components are generated on the backchannel-side surface 150b because the photoresist PR is formed on the backchannel-side surface 150b.

FIG. 6 is a diagram showing a thin film transistor according to an embodiment. FIG. 6 corresponds to the thin film transistor 100 after removing the photoresist PR in FIG. 5. In the semiconductor layer 150, an area between the source electrode 171 and the drain electrode 172 is the channel CH. Although an area of the channel CH in a channel width direction (depth direction in FIG. 6) is not shown in FIG. 6, as generally defined, the channel CH includes an area sandwiched between the source electrode 171 and the drain electrode 172 in an area where the semiconductor layer 150 and the gate electrode 120 overlap in the case where the thin film transistor 100 is viewed in a direction perpendicular to the substrate.

It has been found by the inventors that in order to reduce the negative shift of the thresholds due to the NBTS, it is essential to reduce carbon residual components on a surface of the channel CH. That is, it is preferable that a surface of the channel CH on the side of the gate electrode 120 (hereinafter, referred to as a gate-side surface 150g) and the surface on the opposite side (backchannel-side surface 150b) have less carbon residual components.

On the other hand, as described above, in the state where the surface of the channel CH is exposed, the carbon residual components may be increased by various manufacturing processes. It is meaningless to temporarily reduce the carbon residual components, and it is significant that the carbon residual components on the surface of the channel CH are reduced when the surface of the channel CH becomes unexposed, that is, in the state where the surface of the channel CH becomes covered with other layers. Further, after the surface of the channel CH becomes unexposed, it is difficult to desorb the carbon residual components from the surface of the channel CH.

Since a source surface 150s and a drain surface 150d are not parts that function as the channel CH, the carbon residual components may not be reduced. The source surface 150s corresponds to a part of the surface of the semiconductor layer 150 that is in contact with the source electrode 171. The drain surface 150d corresponds to a part of the surface of the semiconductor layer 150 that is in contact with the drain electrode 172.

In this example, as shown in FIG. 6, at least one of a UV ozone treatment and the heat treatment is executed while part of the backchannel-side surface 150b (an area between the source surface 150s and the drain surface 150d) is exposed. In the UV ozone treatment, ultraviolet rays are irradiated in an oxygen-containing atmosphere. The carbon residual components in the exposed part of the backchannel-side surface 150b are decomposed, and the carbon atoms are desorbed from the surface by ozone obtained by the ultraviolet irradiation, more specifically, active oxygen generated from ozone. The heat treatment is performed at 350° C. or higher, more preferably at 370° C. or higher in the oxygen-containing atmosphere. The carbon residual components in the exposed part of the backchannel-side surface 150b are decomposed, and the carbon atoms are desorbed from the surface by the heat treatment in the oxygen-containing atmosphere.

The oxygen-containing atmosphere may include the air, and may include atmosphere having an oxygen concentration higher than that of the air. The oxygen-containing atmosphere does not exclude atmosphere having an oxygen concentration lower than that of the air if oxygen is contained.

A condition of the UV ozone treatment or a condition of the heat treatment is set such that an average concentration of the carbon atoms in an area from the exposed part of the backchannel-side surface 150b to the depth of 5 nm is reduced to 1.5×10²¹ cm⁻³ or less as a result of the desorption of the carbon atoms. It is preferable that the average concentration of carbon atoms in the area from the exposed part of the backchannel-side surface 150b to the depth of 5 nm is reduced to 3.5×10²⁰ cm⁻³ or less.

The condition of the UV ozone treatment or the condition of the heat treatment may be set such that, as a result of the desorption of the carbon atoms, a maximum concentration of the carbon atoms in the area from the exposed part of the backchannel-side surface 150b to the depth of 5 nm is reduced to 19 at % or less as measured by an Auger electron spectroscopy. The maximum concentration of carbon atoms in the area from the exposed portion of the backchannel-side surface 150b to the depth of 5 nm is preferably reduced to 8 at % or less. For example, the conditions of the UV treatment are, for example, UV light intensity, exposure time, oxygen concentration, substrate temperature, and the like. The conditions of the heat treatment are, for example, heating temperature, heating time, oxygen concentration, and the like.

Other than the exposed part of the backchannel-side surface 150b, that is, the source surface 150s is covered with the source electrode 171, and the drain surface 150d is covered with the drain electrode 172. Therefore, even if the source surface 150s and the drain surface 150d are subjected to the UV ozone treatment or the heat treatment, the carbon residual components are hardly desorbed, and the carbon atoms are more concentrated than the exposed parts of the backchannel-side surface 150b. However, since the source surface 150s and the drain surface 150d do not function as channels of the thin film transistor 100, the presence of carbon residual components has little effect.

For the gate-side surface 150g, there is no factor that causes carbon residual components. Even if the carbon residual components are present on the gate insulating layer 130 before the ITZO film is formed on the gate insulating layer 130, the carbon residual component is reduced by a process (sputtering containing oxygen) when the ITZO film is formed by the PVD method. As a result, the carbon atoms are desorbed and fall within the concentration range described above. In addition, although the gate insulating layer or the semiconductor layer is usually manufactured by a gas phase method, in the case where the gate insulating layer or the semiconductor layer is manufactured by a liquid phase method instead of the gas phase method, there is a factor that the carbon residual components are also generated in the gate-side surface 150g.

After the process of reducing the carbon residual component, an interlayer insulating layer 200 is formed to cover the thin film transistor 100. The thin film transistor 100, in particular a portion contacting the exposed portion of the backchannel-side surface 150b, is protected from carbon atoms by an inorganic insulating material containing a small carbon component so that no carbon residual components are generated again. That is, after the carbon atoms are desorbed from the surface of the channel CH, an insulating layer that protects the channel CH is formed prior to the formation of the layer containing carbon atoms on the surface of the channel CH.

In this example, the interlayer insulating layer 200 includes a structure in which the silicon oxide film, the silicon nitride film, and an organic resin film are stacked in this order from the thin film transistor 100 side. Films of inorganic insulating materials are formed by the CVD method or the PVD method. When forming a film of the inorganic insulating material, a film forming method in which the introduction of carbon atoms is necessary is not adopted. For example, forming aluminum oxide by an ALD (Atomic Layer Deposition) method is not preferable because carbon-containing trimethylaluminum (TMA) is used. However, this type of aluminum oxide can also be used as an inorganic insulating material that does not touch the surface of the channel CH. If it is possible to reduce the number of carbon residual components that eventually occur on the surface of the channel CH by setting the deposition temperature or the like, the inorganic insulating material may be used as the inorganic insulating material that contacts the surface of the channel CH by the ALD method. The organic resin film is formed by a solution coating method or a printing method. A contact hole communicating to the drain electrode 172 is formed in the interlayer insulating layer 200.

The pixel electrode 300 is formed on the interlayer insulating layer 200 and is connected to the drain electrode 172 via the contact hole. The pixel electrodes 300 are formed by, for example, the PVD method. The configuration after the pixel electrode 300 is formed corresponds to FIG. 7. As shown in FIG. 8, the bank layer 400 is formed on the end portion of the pixel electrode 300 and the interlayer insulating layer 200, and further, the light emitting layer 500 and the counter electrode 600 are formed. By forming the sealing layer 900 and covering the first substrate 1 with the second substrate 2, the display device 1000 shown in FIG. 2 is manufactured.

According to the thin film transistor 100 described above, since the carbon atoms are desorbed from the channel CH surface by the treatment of reducing the carbon residual components adsorbed on the surface of the channel CH and the insulating layers covering the channel CH surface are formed prior to the material containing the carbon atoms contacting the channel CH surface, the negative shift of the thresholds due to the NBTS is reduced.

### Experimental Example

Next, we explain the experimental findings that the reduction of carbon residual components enabled us to reduce the negative shift of the thresholds due to the NBTS. As described above, the inventors have found that the negative shift of the thresholds in the NBTS can be reduced by reducing the carbon residual components on the channel CH surface. In order to verify this, a thin film transistor for threshold shift measurement was fabricated.

FIG. 9 is a diagram showing a thin film transistor for threshold shift measurement. The thin film transistor for threshold shift measurement includes a gate electrode 125, a gate insulating layer 135 on the gate electrode 125, a semiconductor layer 155 on the gate insulating layer 135, a source electrode 176 connected to the semiconductor layer 155, and a drain electrode 177. The source electrode 176 and the drain electrode 177 are arranged to sandwich the channel CH. A surface of the channel CH on the gate electrode 125 side is a gate-side surface 155g, and an opposing surface thereof is a backchannel-side surface 155b. A part of the semiconductor layer 155 in contact with the source electrode 176 is the source surface 155s. A part of the semiconductor layer 155 in contact with the drain electrode 177 is the drain surface 155d. In this embodiment, the backchannel-side surface 155b includes an exposed part of the channel CH surface, the source surface 155s, and the drain surface 155d.

The gate electrode 125 is a conductive P-type silicon substrate. The gate insulating layer 135 is a thermal oxide film formed on the surface of the silicon substrate and has a thickness of 150 nm. The semiconducting layer 155 is ITZO and has a thickness of 20 nm. The composition ratio In (indium):Sn (tin):Zn (zinc) excluding O (oxygen) is 20:40:40 (at %). This composition ratio is based on the amount of the elements charged (nominal value) and corresponds to the composition ratio of a target in the case where the target is single. The composition ratio of the actually formed semiconductor layer 155 is shown as Auger electron spectroscopy measurement results described later. In the actual semiconductor layer 155 (also in the semiconductor layer 150 described above), a portion having 10 at % of Sn or more and a portion having 13 at % of Sn or more may be contained in an area from the surface to the depth of 5 nm of the channel CH. In the area from the surface to the depth of 5 nm of CH of channel, the atomic percent of Sn may include a portion greater than the atomic percent of Zn. In the case where Sn is highly concentrated, although the carbon residual components are likely to be generated, the carbon residual components can be reduced as described below, which is not a major issue. The length (channel length) of the channel CH of the thin film transistor is 30 μm, and the channel width is 60 μm. From the viewpoint of miniaturization, the channel length is preferably 100 μm or less, more preferably 30 μm or less, still more preferably 10 μm or less, and still more preferably 3 μm or less. Next, a method of manufacturing a thin film transistor for threshold shift measurement will be described.

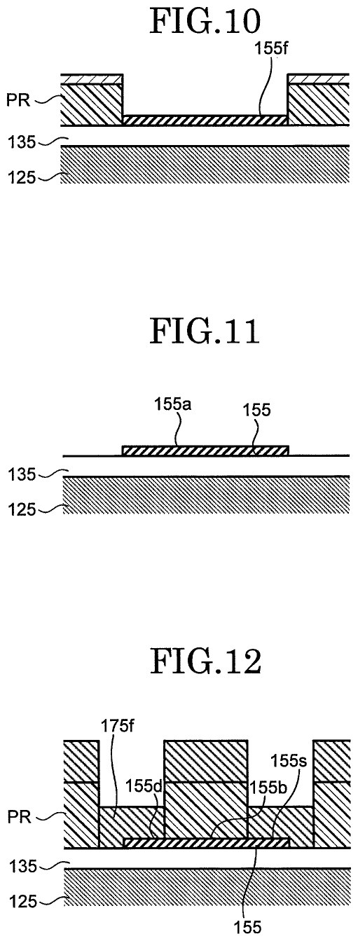

FIG. 10 to FIG. 12 are diagrams for explaining a method of manufacturing a thin film transistor for measurement. The gate electrode (P-type silicon substrate) 125 on which the gate insulating layer 135 (thermal oxide film) is formed is prepared, a photoresist PR is formed and a ITZO film 155f is further formed as shown in FIG. 10. As shown in FIG. 11, if the photoresist PR is removed by the lift-off process, the ITZO film 155f is removed along with the photoresist PR to form the semiconductor layer 155. Although the photoresist PR before being patterned contacts the gate insulating layer 135, the gate insulating layer 135 has no carbon residual component. Even if a slight carbon residual component is present, the carbon residual component is desorbed by sputtering in an oxygen-containing atmosphere when the ITZO film 155f is formed by the PVD method.

As shown in FIG. 12, a photoresist PR is formed and a gold film 175f is further formed. When the photoresist PR is formed, the photoresist PR contacts the upper surface 155a of the semiconducting layers 155. As shown in FIG. 12, the photoresist PR remains in contact with the backchannel-side surface 155b even after patterning. If the photoresist PR is removed by the lift-off process, the source electrode 176 and the drain electrode 177 are formed as shown in FIG. 9. In this case, the exposed part of the backchannel-side surface 155b, the source surface 155s, and the drain surface 155d have carbon residual components. As described above, the heat treatment or the UV ozone treatment reduces the carbon residual components in the exposed part of the backchannel-side surface 155b.

[Carbon Residual Components]

An ITZO film was formed on the substrate, a sample prior to forming the photoresist (hereinafter referred to as a Before PR sample) and a sample from which the photoresist was removed after forming the photoresist on the ITZO film (hereinafter referred to as a After PR sample) were prepared, and a TDS (Thermal Desorption Spectrometry) measurement and a HAX-PES (Hard X-ray Photoelectron Spectroscopy) measurement were performed.

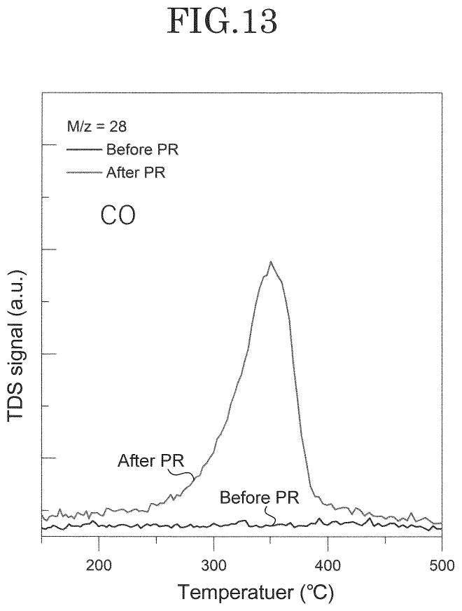

FIG. 13 is a graph showing TDS measurement results before photoresist formation and after photoresist formation/removal. According to FIG. 13, no CO is detected in the Before PR sample. On the other hand, it is confirmed that CO of the After PR sample desorbs at around 350° C. That is, if the photoresist is formed, even if the photoresist is removed by a stripping solution or the like, it is confirmed that CO is present on the ITZO film as a carbon residual component.

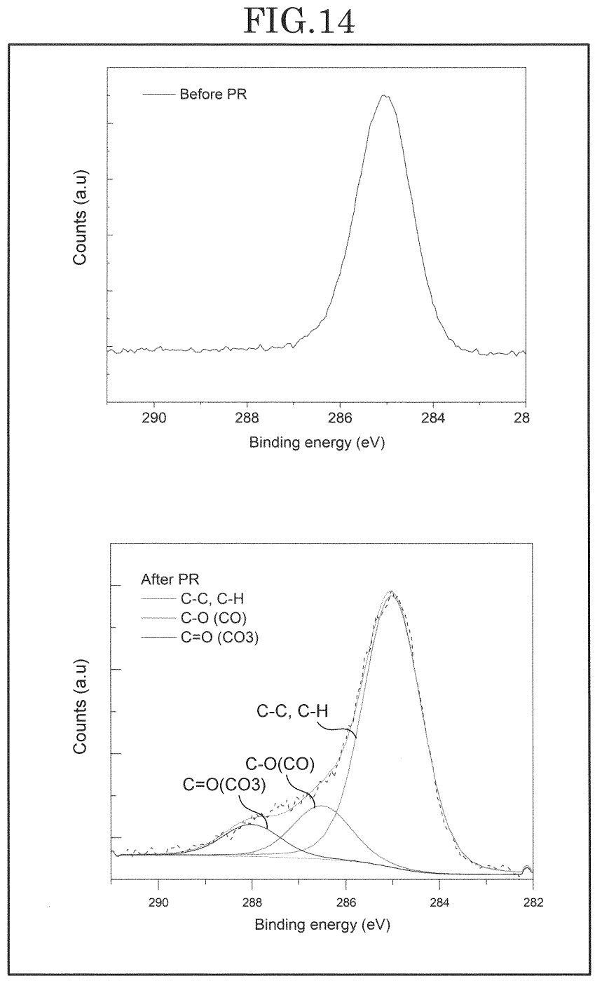

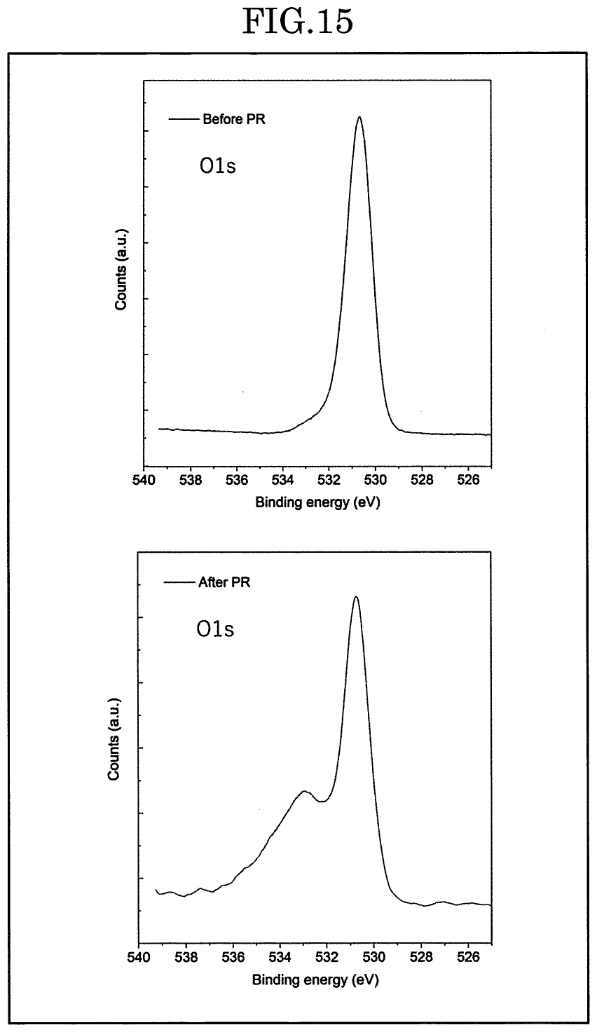

FIG. 14 and FIG. 15 are graphs showing HAX-PES measurement results before photoresist formation and after photoresist formation/removal. According to the results of FIG. 14 (C1s) and the results of FIG. 15 (O1s), although no peaks for “C—O” and “C═O” were detected in the Before PR samples, the peaks are detected in the After PR samples. This small peak comes from carbon. That is, it has been confirmed that carbon residual components are present in the After PR samples.

[Effect of Heat Treatment on Carbon Residual Components]

An effect of the heat treatment for the After PR sample on the desorption of the carbon residual components was confirmed.

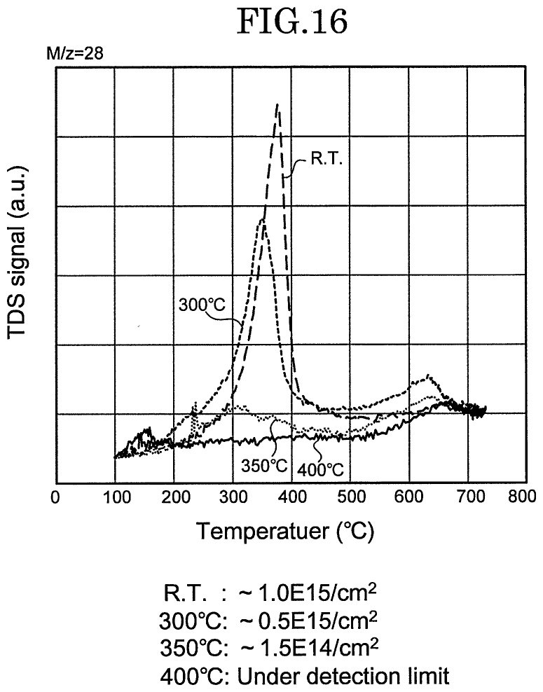

FIG. 16 is a graph showing TDS measurement results according to the heating temperature. With respect to the After PR sample, a sample which is not heat-treated (R. T.), a sample heat-treated at 300° C. for 1 hour, a sample heat-treated at 350° C. for 1 hour, and a sample heat-treated at 400° C. for 1 hour were prepared. The TDS measurement result for each After PR sample showed that the higher the temperature of the heat treatment, the lower the quantity of CO desorbed. That is, it was confirmed that the carbon residual component decreases as the heating temperature increases.

Specifically, the desorption quantity of CO is 1.0×10¹⁵ cm⁻² in the case of the After PR sample which is not heat-treated (R. T.), 0.5×10¹⁵ cm⁻² in the case of the After PR sample which is heat-treated at 300° C. for 1 hour, 1.5×10¹⁴ cm⁻² in the case of the After PR sample which is heat-treated at 350° C. for 1 hour, and the After PR sample which is heat-treated at 400° C. for 1 hour was at the lower limit of detection (1.0×10¹⁴ cm⁻²) or less.

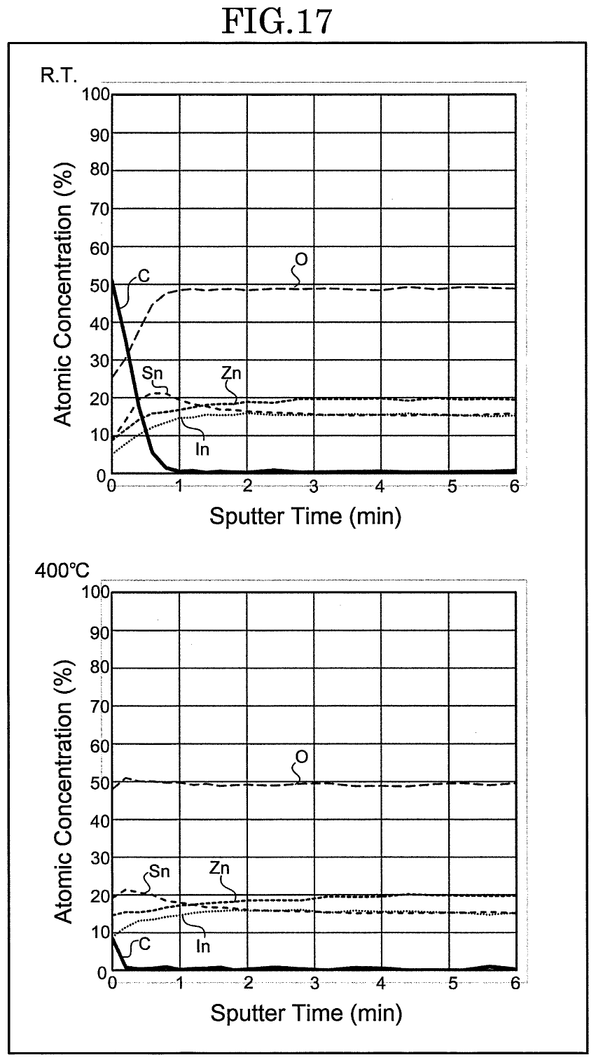

FIG. 17 is a graph showing results of Auger electron spectroscopy for the After PR sample and the sample after the heat treatment. The horizontal axis corresponds to time (Sputter Time) of etching (sputtering) the surface of the ITZO with an Ar ion beam. In this example, an etch rate of ITZO is 2.5 nm/min. Depth-wise compositional fraction (Atomic Concentration) was obtained by repeating the etching and Auger electron spectroscopy measurement. In the case where the After PR sample is not heat-treated, carbon atoms are detected at a depth from the surface of the ITZO film to 2 nm or 3 nm. In particular, 50 at % of carbon atoms have been detected at the outermost surface. On the other hand, in the case where the heat treatment of 400° C. is performed on the After PR sample, although 8 at % of carbon atoms is detected at the outermost surface, at a depth less than 1 nm from the surface of the ITZO film, the lower limit of the carbon atom detection is detected.

Considering the results of the TDS measurements and the results of the Auger electron spectroscopy measurements, CO desorption is 1.0×10¹⁵ cm⁻² in the case of the After PR samples which are not heat-treated (R. T.), and 50 at % of carbon atoms were measured at the outermost surface. In this case, based on a relationship described below, it can be said that an average concentration of carbon atoms ranging from the surface to the depth of 5 nm of the ITZO film is about 1.0×10²² cm⁻³ and is at least more than 1.5×10²¹ cm⁻³.

For the After PR sample which is heat-treated at 400° C. for 1 hour, CO desorption is below the lower limit of detection (1.0×10¹⁴ cm⁻²) by TDS and 8 at % of carbon was measured at the outermost surface by Auger electron spectroscopy. In this case, it can be said that the average concentration of carbon atoms in an area from the surface to the depth of 5 nm of the ITZO film is 3.5×10²⁰ cm⁻³.

In the case of the After PR sample heat-treated at 350° C. for 1 hour, the CO desorption amount is 1.5×10¹⁴ cm⁻². Considering the TDS measurement results, the highest concentration of carbon atoms at the outermost surface is estimated to be 19 at % in the case where the heat treatment is performed at 350° C. for the sample after the heat treatment. In this case, it can be said that the average concentration of carbon atoms in an area from the surface to the depth of 5 nm of the ITZO film is 1.5×10²¹ cm⁻³.

A relationship between the results of the TDS measurements and the results of the Auger electron spectroscopy measurements and the carbon-atom concentration is explained. ITZO has an atomic count of approximately 8.0×10²² cm⁻³ per unit volume (1 cubic centimeter) in view of molecular weight and film density. According to the results of the Auger electron spectroscopy measurement, the total amount of C relative to the total amount of In, Sn, Zn and O contained in the depth of 5 nm from the surface of ITZO film (sputtering time: 2 minutes) is hereinafter referred to as carbon-relative concentration. The carbon-relative concentration is obtained as a value obtained by integrating the atomic percentage of C in the range from the surface to a depth of 5 nm relative to a value (100×5) obtained by integrating 100% in the range from the surface to a depth of 5 nm.

According to the After PR samples without the heat treatment, the carbon-relative concentration is approximately 12.5%. By multiplying the relative carbon concentration by the number of atoms per unit volume described above, the number of carbon atoms per unit volume can be obtained. The number of carbon atoms per unit volume corresponds to the average concentration in an area from the surface to the depth of 5 nm, hereinafter referred to as a carbon atom concentration.

In the case of the After PR sample without the heat treatment, the carbon atom concentration is calculated as about 1.0×10²² cm⁻³. On the other hand, in the case of the After PR sample which is heat-treated at 400° C. for 1 hour, a calculated carbon atom concentration is 3.5×10²⁰ cm⁻³. Here, according to the TDS measurement results, the After PR sample which is heat-treated at 350° C. for 1 hour has a CO desorption amount of 0.15 times that of the After PR sample which is not heat-treated. Therefore, a carbon atom concentration is estimated to be 1.5×10²¹ cm⁻³ in the case of After PR samples heat-treated at 350° C. for 1 hour.

Considering profiles of the carbon atoms of the Auger electron spectroscopy measurement of the After PR sample which is not heat-treated and the After PR sample which is heat-treated at 400° C. for 1 hour and the carbon atom concentration described above, it is estimated from the carbon atom concentration that the highest concentration of carbon atoms at the outermost surface is 19 at % in the case of the After PR sample heat-treated at 350° C. for 1 hour.

A position of the channel CH in the semiconductor layer 150 in the thin film transistor 100 may be defined as follows. In the case of the backchannel-side surface 150b, if measured by Auger electron spectroscopy as described above from an inorganic insulating film of the adjacent interlayer insulating layer 200 toward the semiconductor layer 150 (channel CH), the position where In, Sn and Zn are detected is defined as the surface. On the other hand, in the case of the gate-side surface 150g, if measured by Auger electron spectroscopy as described above from the neighboring gate insulating layer 130 toward the semiconductor layer 150 (channel CH), the position where In, Sn and Zn are detected is defined as the surface.

[Effect on NBTS]

In the thin film transistor for threshold measurement, as shown in FIG. 9, after the source electrode 176 and the drain electrode 177 were formed, a thin film transistor which is not heat-treated (R. T.), a thin film transistor heat-treated at 300° C. for 1 hour, a thin film transistor heat-treated at 350° C. for 1 hour, and a thin film transistor heat-treated at 400° C. for 1 hour were prepared. The NBTS was performed on these thin film transistors for measurement. In the NBTS, the voltage of the gate electrode with respect to the source electrode and the drain electrode was controlled to be “Vth−20 V” while maintaining the temperature at 60° C. and a dark state. A duration of the application of the NBTS is up to 3600 seconds.

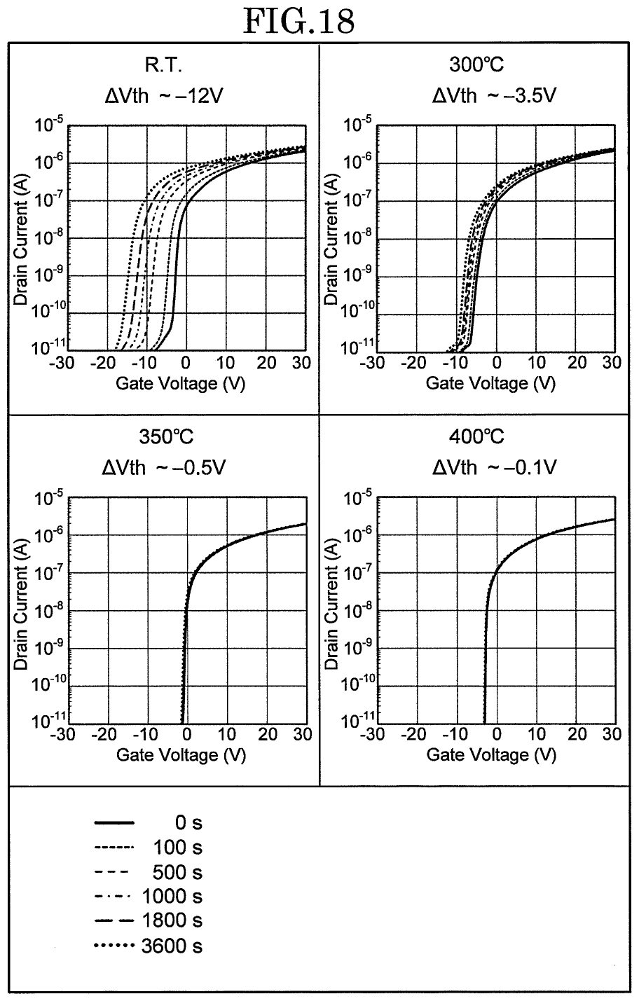

FIG. 18 is a graph showing measurement results of a threshold shift due to the NBTS. Id (Drain Current)−Vg (Gate Voltage) property shown in FIG. 18 indicates the drain current when the voltage of the gate electrode 172 is varied in a condition that the voltage of the drain electrode 177 with respect to the source electrode 176 is controlled to be “0.1 V”. FIG. 18 shows NBTS time-dependency of the threshold shift in accordance with the respective heat treatment conditions. As shown in FIG. 18, a shifting of the thresholds before the NBTS was “−12 V” in the case where the heat treatment was not performed, “−3.5 V” in the case of a 300° C. heat treatment, “−0.5 V” in the case of a 350° C. heat treatment, and “−0.1 V” in the case of a 400° C. heat treatment. From this result, it was confirmed that the smaller the presence of the carbon residual component, the smaller the amount of the negative shift. If the amount of the threshold shift in the case of the 350° C. heat treatment is reduced, sufficient reliability in practical use can be obtained.

[Effect on NBIS]

In the thin film transistor for threshold measurement, after the source electrode 176 and the drain electrode 177 were formed as shown in FIG. 9, a thin film transistor which is not heat-treated (R. T.) and a thin film transistor heat-treated at 400° C. for 1 hour were prepared. NBIS (Negative Bias Illumination Stress) was performed on these thin film transistors. In the NBIS, a voltage of the gate electrode with respect to the source electrode and the drain electrode was controlled to be “Vth−20 V” and maintained under 4000 lux photoirradiation. A duration of the application of the NBIS is up to 3600 seconds.

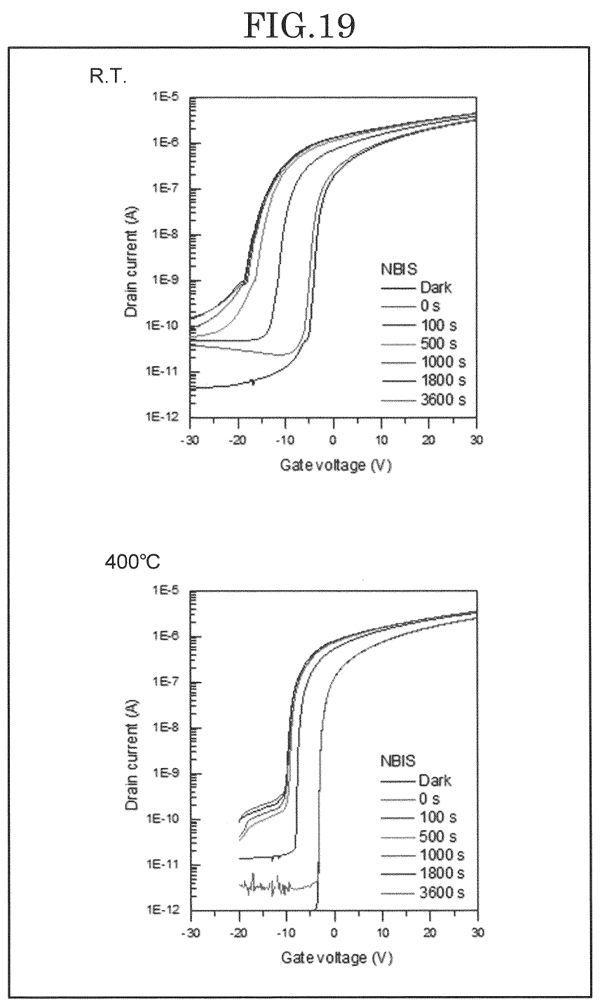

FIG. 19 is a graph showing measurement results of a threshold shift due to the NBIS. Id-Vg property shown in FIG. 19 indicates a drain current when the voltage of the gate electrode 172 is varied in a condition that the voltage of the drain electrode with respect to the source electrode is controlled to be “0.1 V”. FIG. 19 shows the NBIS time-dependency of the threshold shift in accordance with the respective heat treatment conditions. As shown in FIG. 19, the amount of the threshold shift is “−12.5 V” in the case where the heat treatment was not performed, and “−6.5 V” in the case where the heat treatment was performed at 400° C. From this result, it was confirmed that, even under light irradiation, the smaller the presence of the carbon residual component, the smaller the amount of the negative shift.

In the case where a thin film transistor having the amount of the threshold shift of “−6.5V” due to the NBIS is used in a display device and the amount of this shift is problematic, a light shielding layer may be provided in the vicinity of the thin film transistor so as to prevent a light entry path to the channel CH. Since the intrusion of light is prevented by the light shielding layer, the negative shift of the threshold can be further reduced, and thus reliability of the thin film transistor can be improved.

Although the light shielding layer is not included in a display device according to an embodiment, the light shielding layer may be arranged in the upper layer or the lower layer of the thin film transistor 100 so as to prevent the light from entering the channel CH. By reducing the carbon residual component, the amount of the threshold shift is reduced even under light irradiation. Therefore, in order to achieve the amount of the threshold shift necessary for ensuring reliability, the amount of light to be shielded can also be reduced. As a result, by reducing the carbon residual component, the light-shielding layer arranged around the thin film transistor 100 can be made small or omitted.

[Effect of UV Ozone Treatment on Carbon Residual Components]

An effect of the UV ozone treatment on the After PR samples on the desorption of carbon residual components was confirmed.

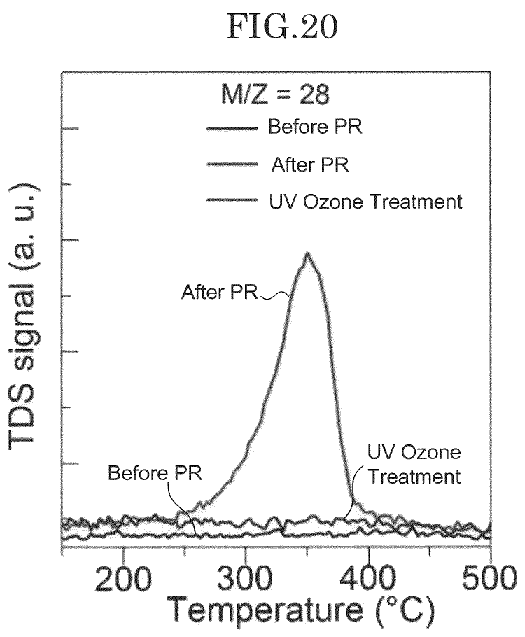

FIG. 20 is a graph showing the TDS measurement results after photoresist formation/removal and after a UV ozone treatment. The relationship between the Before PR sample and the After PR sample is the same as the relationship described above. TDS measurement result of the UV ozone treatment (UV Ozone Treatment) at room temperature for the After PR sample was equivalent to that for the Before PR sample. That is, it was confirmed that the UV ozone treatment reduced the carbon residual components from the ITZO film, which was equivalent to the state prior to forming the photoresist.

Since the UV ozone treatment can be performed even at room temperature, even if the thin film transistor 100 shown in FIG. 6 contains a material having a low heat resistance until the thin film transistor is formed, the carbon residual component can be desorbed. Although not shown, for example, in the case where an organic insulating film such as color filters is present between the thin film transistor 100 and the first supporting substrate 10, it is beneficial to reduce the carbon residual components by the UV ozone treatment instead of the heat treatment.

[Effect on NBTS]

In thin film transistors for threshold measurement, a UV ozonated thin film transistor was prepared after the source electrode 176 and the drain electrode 177 were formed as shown in FIG. 9. The NBTS was performed on these thin film transistors for measurement. The condition of the NBTS is the same as the condition when the measurement results shown in FIG. 18 were obtained, and a condition in which the voltage of the gate electrode with respect to the source electrode and the drain electrode was controlled to be “Vth−20 V” while maintaining the temperature at 60° C. and a dark state was adopted. PBTS (Positive Bias Temperature Stress) in which the voltage of the gate electrode with respect to the source electrode 176 and the drain electrode 177 was controlled to be “Vth+20 V” while maintaining the temperature at 60° C. and a dark state was performed.

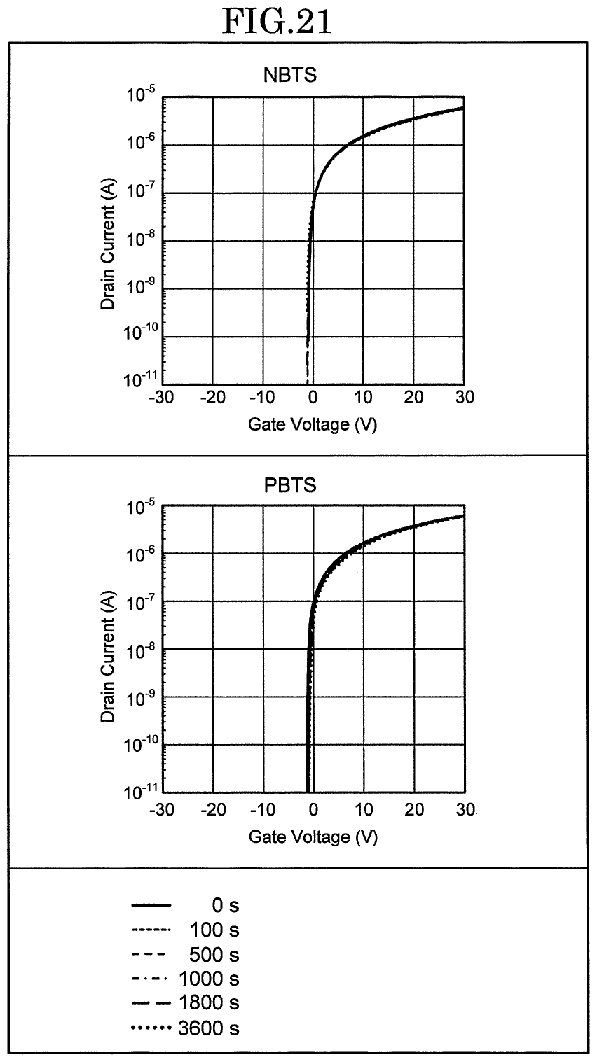

FIG. 21 is a graph showing measurement results of the threshold shift due to the NBTS and the PBTS after the UV ozone treatment. Id-Vg property shown in FIG. 21 indicates a drain current when the voltage of the gate electrode 172 is varied in a condition that the voltage of the drain electrode 177 with respect to the source electrode 176 is controlled to be “0.1 V”. As shown in FIG. 21, even in the UV ozone treatment, the amount of the threshold shift due to the NBTS is kept sufficiently small.

The amount of the threshold shift due to the PBTS is kept sufficiently small as in the case of the NBTS. Although omitted in the above explanation, the PBTS is presented for reference because the amount of the threshold shift is kept small without reducing the carbon residual components (the UV ozone treatment or the heat treatment) with respect to the After PR sample.

[Modification]

The present disclosure is not limited to the embodiments described above, and includes various other modifications. For example, the embodiments described above have been described in detail for the purpose of showing the present disclosure clearly, and are not necessarily limited to those having all the described configurations. It is possible to add, delete, or replace a part of the configuration of each embodiment with another configuration. Some modification examples will be described below.

[Thin Film Transistor with Other Structure]

The thin film transistor used in the display device 1000 is not limited to the thin film transistor 100 in the embodiment described above, and thin film transistors having various structures can be adopted. In the following description, two exemplary configurations of a thin film transistor containing ITZO will be described.

The thin film transistor 100 is a BCE thin film transistor, but an ESL (Etch Stop Layer) thin film transistor may be applied to the display device 1000.

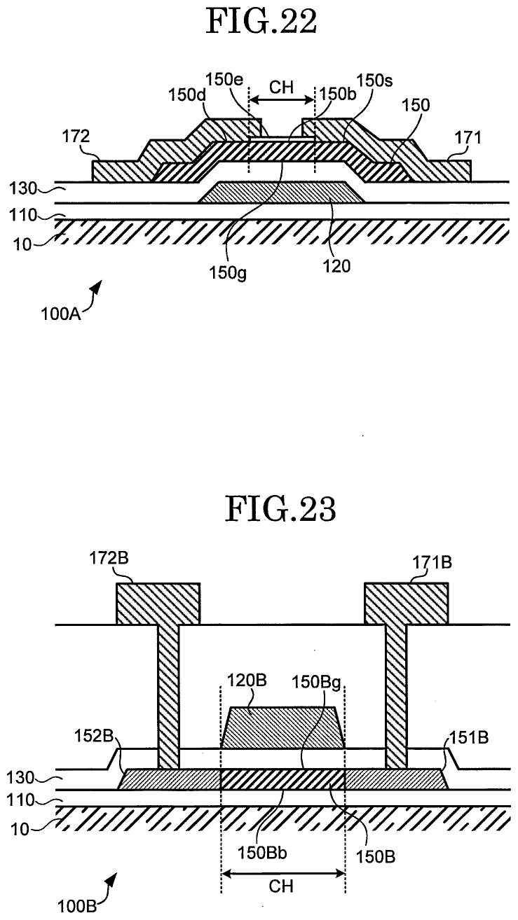

FIG. 22 is a diagram showing an ESL thin film transistor according to an embodiment. In FIG. 22, an ESL thin film transistor 100A is shown. The thin film transistor 100A has a configuration in which an etch-stop layer 150e is added to the thin film transistor 100. The etch-stop layer 150e is a layer that serves as an etch stopper when the source electrode 171 and the drain electrode 172 are formed, and is, for example, silicon oxide formed by the CVD method or the PVD method. When forming the source electrode 171 and the drain electrode 172, the exposed part of the backchannel-side surface 150b is covered with the etch-stop layer 150e. Therefore, in the ESL thin film transistor 100A, after the semiconductor layer 150 is formed, the treatment (heat treatment or UV ozone treatment) for desorbing the carbon residual components is performed prior to forming the silicon oxide film serving as the etch-stop layer 150e. That is, the etch-stop layer 150e functions as an insulating layer covering the channel.

In the ESL thin film transistor 100A, a position where the source electrode 171 and the drain electrode 172 are in contact with the semiconductor layer 150 due to the presence of the etch-stop layer 150e differs from the BCE thin film transistor 100. Therefore, as shown in FIG. 22, an area of the channel CH of the thin film transistor 100A differs from the channel CH of the thin film transistor 100.

Although the thin film transistor 100 is a bottom-gate thin film transistor, a top-gate thin film transistor may be applied to the display device 1000.

FIG. 23 is a diagram showing a top-gate thin film transistor according to an embodiment. In the bottom gate thin film transistor 100, the gate electrode 120 is arranged between the first supporting substrate 10 and the semiconductor layer 150. On the other hand, as shown in FIG. 23, in a top-gate thin film transistor 100B, a semiconductor layer 150B is arranged between the first supporting substrate 10 and a gate electrode 120B. Therefore, although the surface on which the photoresist PR contacts when the ITZO film is processed is the backchannel-side surface 150b in the case of the bottom-gate thin-film transistor 100, the surface is the gate-side surface 150Bg in the case of the top-gate thin film transistor 100B. Therefore, in the top-gate thin film transistor 100B, a treatment (heat treatment or UV ozone treatment) for desorbing the carbon residual components is performed after the semiconductor layer 150B is formed prior to the formation of the gate insulating layer 130. Note that, in the backchannel-side surface 150Bb, the carbon residual component is not present or the carbon residual component is desorbed when the ITZO film is formed as described above even if the carbon residual component is slightly present.

In the top-gate thin film transistor 100B, a part of the semiconductor layer 150B immediately below the gate electrode 120B corresponds to the channel CH. A source area 151B is formed on a source electrode 171B side with respect to the channel CH, and a drain area 152B is formed on a drain electrode 172B side with respect to the channel CH. For example, the source area 151B and the drain area 152B are, for example, areas in which the resistivity is reduced by supplying hydrogen or the like to the semiconductor layer 150B by self-alignment using the gate electrode 120B as a mask.

As described above, even if a thin film transistor having any configuration is applied to the display device 1000, the treatment (heat treatment or UV ozone treatment) may be performed in which the carbon residual components are desorbed while the channel CH is exposed. Then, after the desorption process and prior to the formation of the layer containing carbon atoms (e.g., photoresist, organic insulating layer, and the like) on the channel CH, an insulating layer (e.g., an inorganic insulating material such as silicon oxide) that protects the channel CH from carbon atoms may be formed.

A thin film transistor containing a semiconductive material other than ITZO may be used in combination with the thin film transistor 100. The semiconductor material other than ITZO may be, for example, another metal oxide semiconductor (for example, IGZO) or a semiconductor containing silicon such as amorphous silicon or polysilicon.

[Application to Electronic Appliance]

The display device 1000 described above may be applied as a display of various electronic appliances such as a smartphone, a laptop computer, and a television. The display device 1000 is not limited to the organic EL display including the light-emitting layer whose light emission is controlled by the pixel circuit. For example, the display device 1000 may be a micro LED display in which the light emitting layer is an LED (Light Emitting Diode), or may be a display including an optical element whose optical properties are controlled by the pixel circuit, for example, a liquid crystal display including a liquid crystal as an optical element.

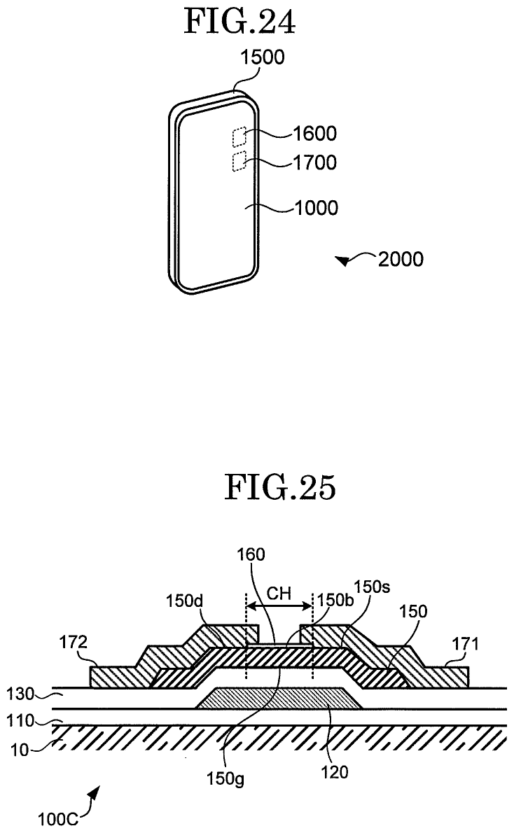

FIG. 24 is a diagram showing an electronic appliance according to an embodiment. An electronic appliance 2000 shown in FIG. 24 is a smartphone, and includes the display device 1000, a control device 1600, and a storage device 1700 housed in a housing 1500. The storage device 1700 is, for example, a nonvolatile memory. The control device 1600 includes a CPU (Central Processing Unit) and the like, and controls the display device 1000 by executing a program stored in the storage device 1700 to control a video displayed on the display device 1000.

The thin film transistor described above is not limited to the case where the thin film transistor is applied to an element constituting the display device 1000, and may be applied to an element constituting the control device 1600, the storage device 1700, and the like. That is, the electronic appliance in which the thin film transistor 100 is included may be a configuration in which the display device 1000 is not provided. Examples of the electronic appliance include an electronic appliance other than a display device, such as a storage device, a logic circuit and a peripheral circuit device thereof, a wireless signal processing device, an input device, an imaging device, a neuromorphic computing device, and the like. A thin film transistor containing a semiconductor material other than ITZO may be further applied to such an electronic appliance in combination with a thin film transistor containing ITZO.

[ZSO Passivation Layers]

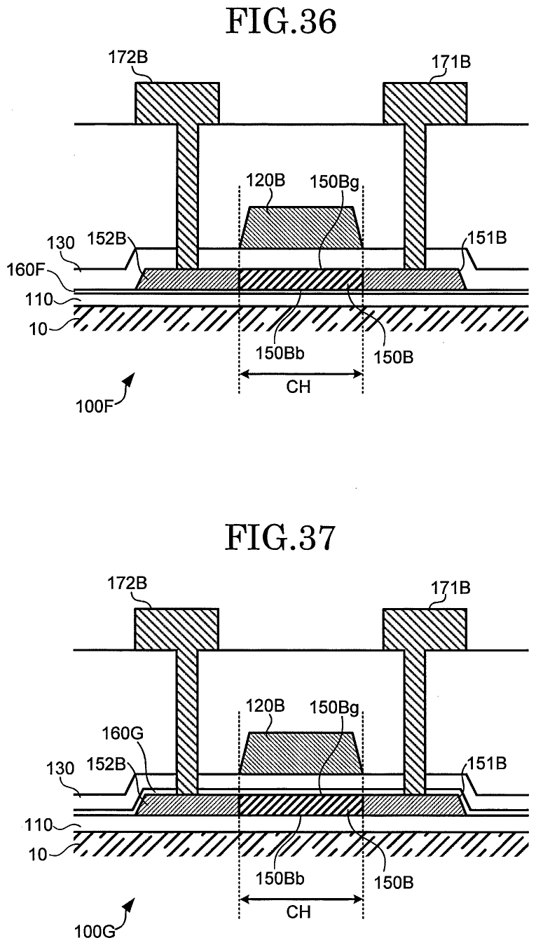

In the thin film transistor 100, the backchannel-side surface 150b in the channel CH may be covered with a passivation layer formed of a predetermined film to form an insulating layer covering the channel. The passivation layer is preferably an oxide thin film that can be formed by a DC sputtering method under an oxygen-containing atmosphere, and is formed by, for example, an amorphous ZSO (ZnSiO) film. From the viewpoint of adhesion, although the passivation layer preferably contains amorphous at least in part, it may contain a crystal structure such as a microcrystal in part. Although a thickness of the passivation layers may be varied, for example, 2 nm or more and 200 nm or less is preferable, and 3 nm or more and 50 nm or less is more preferable. In this example, the thickness of the passivation layers is 5 nm. The passivation layers can also be applied to the top-gate thin film transistor 100B shown in FIG. 23. In this case, as shown in FIG. 36, a passivation layer 160F may be formed between the base insulating layer 110 and the backchannel-side surface 150Bb, or as shown in FIG. 37, a passivation layer 160G may be formed between the gate insulating layer 130 and the gate-side surface 150Bg. The passivation layer 160F and the passivation layer 160G are preferably present at least in the channel CH areas. In other words, the passivation layer 160F and the passivation layer 160G may not be present in areas other than the channel CH, and may cover at least the channel CH.

The ZSO film is formed by the DC sputtering using a target containing ZnO and SiO₂. The ZSO film as the passivation layer has an insulating property. ZSO changes from an insulating state to a conductive state by increasing the ratio of ZnO to SiO₂. The ZSO film can be formed by the DC sputtering because it is formed with a target of ZSO having conductivity. In order to prevent reduction of the surface of the semiconductor layer 150, it is preferable that the target of ZSO be contained as a metal oxide instead of Zn as a metal. On the other hand, the passivation layer of the insulating ZSO film is formed by controlling the conditions of sputtering. The ZSO film may be formed by the PVD method other than the DC sputtering, or may be formed by the CVD method or the ALD method as long as the carbon residual components that eventually occur on the surface of the channel CH can be reduced.

The passivation layer is not limited to a ZSO film which is a metal oxide layer containing Zn and silicon (Si), and may be, for example, a ZSTO film which is a metal oxide layer containing Zn, Si, and Sn. In this case, it may be formed by the DC sputtering in an oxygen-containing atmosphere using a target containing ZnO, SnO₂ or a target containing ZnO, SiO₂, and SnO₂.

In the ZSO film, the molar ratio of Zn/(Zn+Si) is preferably in the range of 0.30 or more and 0.95 or less, and more preferably in the range of 0.40 or more and 0.85 or less. In the ZSTO film, the molar ratio of Sn/(Zn+Sn+Si) is preferably in the range of 0.15 or more and 0.95 or less. The molar ratio of Si/(Zn+Sn+Si) is preferably in the range of 0.07 or more and 0.30 or less. These molar ratios are values in films.

The passivation layers may further contain at least one of titanium (Ti), gallium (Ga), niobium (Nb), aluminum (Al), and In with respect to the ZSO film or the ZSTO film. Also in this case, these elements are preferably contained in the target as a metal oxide.

The electron affinity of the passivation layer is preferably smaller than the electron affinity of the semiconductor layer 150 (in this case, the ITZO film). Further, it is preferable that the electron affinity of the passivation layer is in a range of 2.0 eV or more and 4.0 eV or less, and an ionization potential of the passivation layer is in a range of 6.0 eV or more and 8.5 eV or less. More preferably, the electron affinity is in a range of 2.2 eV or more and 3.5 eV or less, and even more preferably in a range of 2.5 eV or more and 3.0 eV or less. A more preferable ionization potential is in a range of 6.0 eV or more and 7.5 eV or less, more preferably in a range of 6.0 eV or more and 7.0 eV or less. By providing a passivation layer having a smaller electron affinity than that of the semiconductor layer, the passivation layer has an effect of preventing injection of electrons from the outside into the semiconductor layer. Further, by providing a passivation layer having an ionization potential larger than that of the semiconductor layer, it is possible to prevent injection of holes from the outside into the semiconductor layer. As a result, it is possible to reduce the threshold shift due to NBS or PBS (Positive Bias Stress).

The electron affinity of the passivation layer can be adjusted by changing the composition ratio in the target. For example, in the case of the ZSO film, a desired electron affinity can be achieved depending on the ratio of ZnO and SiO₂ in the target. The electron affinity and the ionization potential can be obtained by a known measurement method such as a quantum chemical theory calculation (electron affinity=energy difference between neutral molecules and anions, ionization potential=energy difference between cations and neutral molecules), or a photoelectron spectroscopy. Specifically, the ionization potential is evaluated using an ultraviolet photoelectron spectroscopy, a band gap is evaluated using a spectrophotometer, and the electron affinity is calculated from the difference between the ionization potential and the band gap.

FIG. 25 to FIG. 27 are diagrams showing a thin film transistor including a passivation layer according to an embodiment. In FIG. 25 to FIG. 27, the passivation layer of the ZSO film is applied to the thin film transistor 100. In a thin film transistor 100C shown in FIG. 25, a passivation layer 160 is formed at a position corresponding to the etch-stop layer 150e described above. That is, the ZSO film is formed after the semiconductive layer 150 is formed, and the ZSO film is formed in a desired pattern, whereby the passivation layer 160 is formed on the backchannel-side surface 150b. Part of the passivation layer 160 is covered with the source electrode 171 and the drain electrode 172.

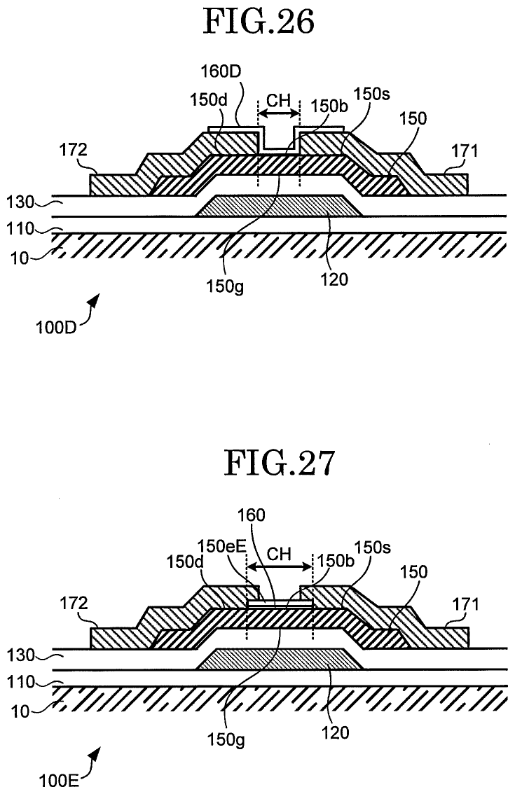

In a thin film transistor 100D shown in FIG. 26, after the source electrode 171 and the drain electrode 172 are formed, the ZSO film is formed in a desired pattern, whereby the passivation layers 160D are formed on the exposed parts of the backchannel-side surface 150b. Similar to the passivation layer 160 in the thin film transistor 100C, a passivation layer 160D covers the exposed part of the backchannel-side surface 150b. On the other hand, unlike the passivation layer 160 in the thin film transistor 100C, the passivation layer 160D also covers part of the source electrode 171 and the drain electrode 172.

A thin film transistor 100E including an etch-stop layer 150eE shown in FIG. 27 is the example in which the etch-stop layer 150e described above is formed on the passivation layer 160 in a thin film transistor 100C shown in FIG. 25. The passivation layer 160 and the etch-stop layer 150eE may be formed in the same pattern. By adjusting the thickness of the passivation layer 160, the passivation layer 160 may function as the etch-stop layer 150e in the thin film transistor 100C shown in FIG. 25.

Thus, the present inventors have found that the passivation layer made of the ZSO film further reduces the threshold shift due to a negative gate-voltage application at 60° C. or under a light irradiation condition. It is considered that the passivation layer reduces the surface level of ITZO and prevents the transfer of charges between ITZO and the outside. Hereinafter, a result of reducing the threshold shift will be described. The thin film transistor for threshold shift measurement corresponds to the thin film transistor for threshold shift measurement shown in FIG. 9. Therefore, the thin film transistor in which the passivation layer made of the ZSO film is formed, is formed on the backchannel-side surface 155b of the thin film transistor shown in FIG. 9. Here, after the thin film transistor shown in FIG. 9 is formed and heat-treated at 400° C., the passivation layer made of the ZSO film is further formed.

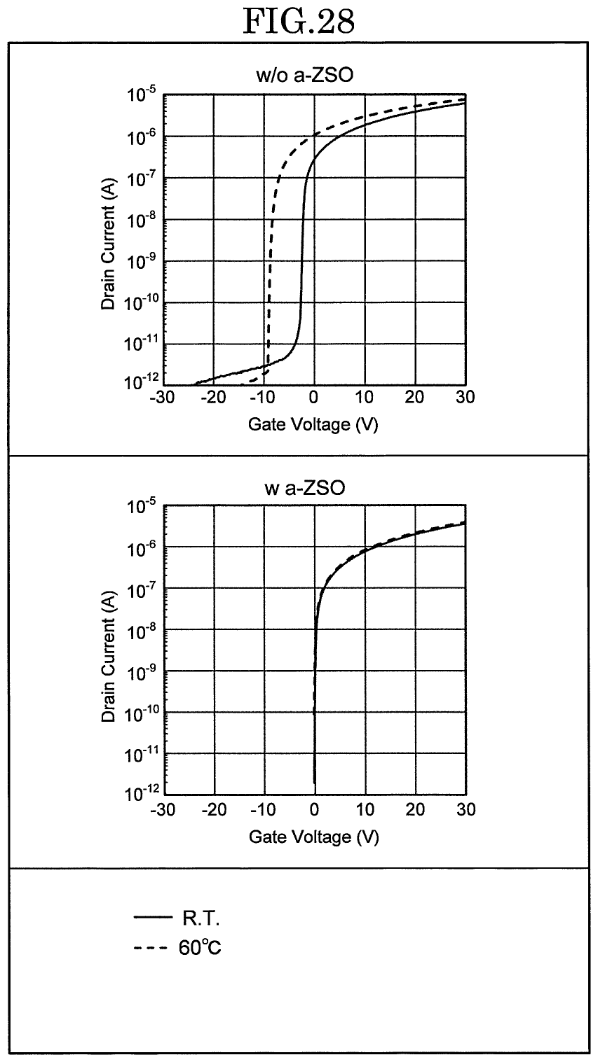

FIG. 28 is a graph showing measurement results of a threshold shift according to a temperature change. Id-Vg property shown in FIG. 28 indicates the drain current when the voltage of the gate electrode 172 is varied in a condition that the voltage of the drain electrode with respect to the source electrode is controlled to be “0.1 V”. FIG. 28 shows Id-Vg property at room temperature (R. T.) and 60° C. without the passivation layer of the ZSO film (w/o a-ZSO) and with the passivation layer of the ZSO film (w a-ZSO).

In the case without the passivation layer of the ZSO film, the threshold at 60° C. is shifted to more negative than the threshold at room temperature. On the other hand, in the case where the passivation layers of ZSO film are used, the thresholds are hardly shifted even at 60° C. than the threshold at room temperature. In this way, the passivation layer of the ZSO film reduces the temperature dependence of the threshold.

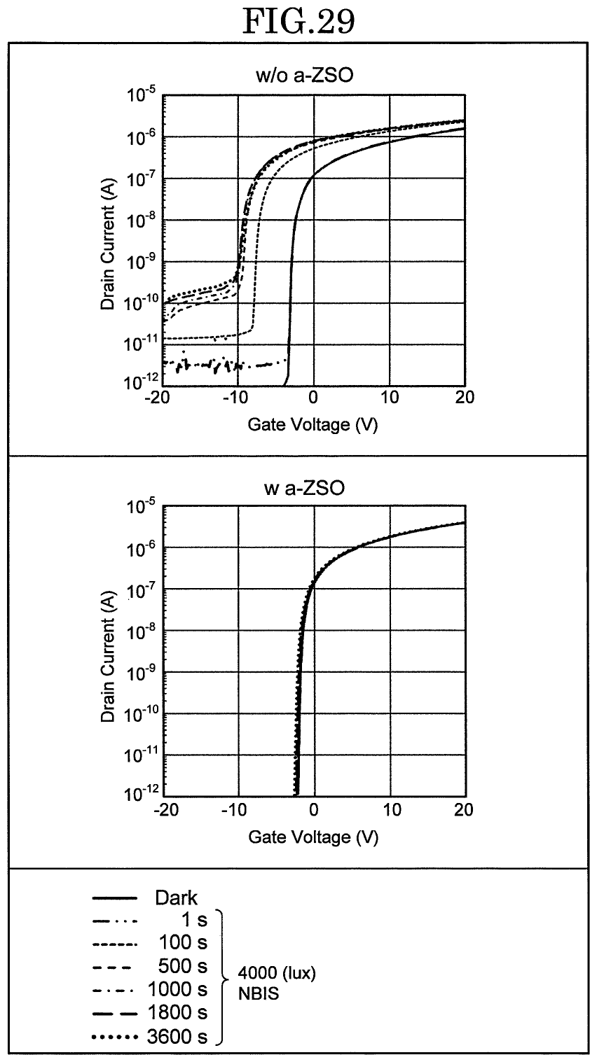

FIG. 29 is a graph showing measurement results of a threshold shift due to the NBIS. FIG. 29 shows measurement results of the NBIS corresponding to FIG. 19 described above, and the result in the case where the passivation layer of the ZSO film is not used corresponds to the case of the 400° C. heat treatment in FIG. 19. On the other hand, in the case where the passivation layer of the ZSO film is used, the threshold is hardly shifted. Thus, the passivation layer of the ZSO film further reduces the negative shift of the threshold due to the NBIS.

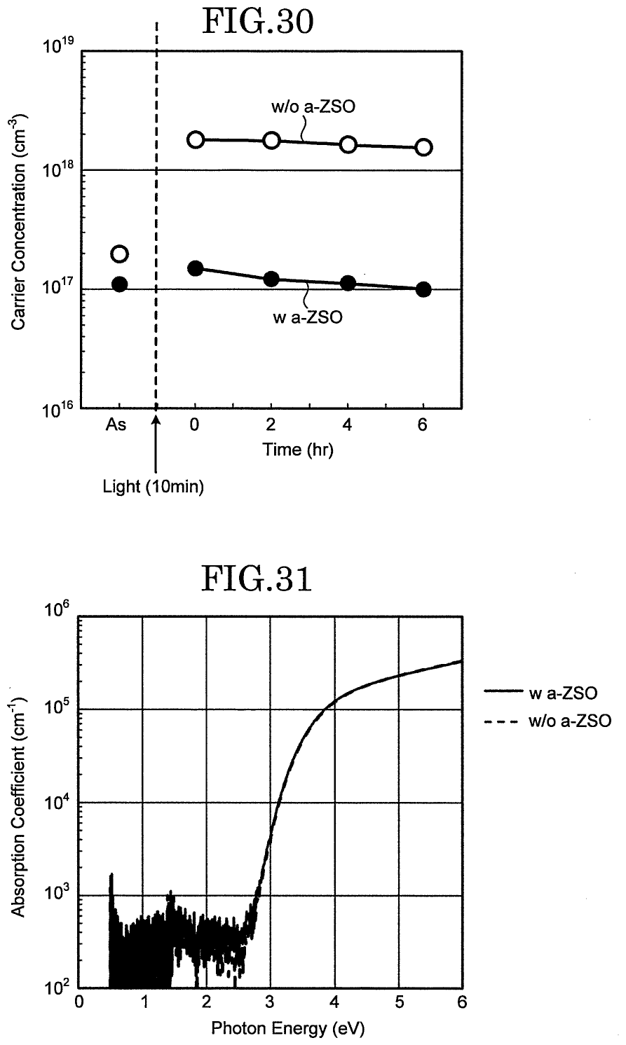

FIG. 30 is a graph showing measurement results of an electron concentration before and after light irradiation. FIG. 30 shows an electron density measurement of an ITZO film by Hall measurement for a sample without the ZSO film formed on a glass-substrate (w/o a-ZSO) and a sample with the ZSO film of 5 nm formed on the ITZO film (w a-ZSO). The electron density was measured before the light irradiation (corresponding to “AS” in a time axis) and after light irradiation, and also measured for time variation after light irradiation (the “0” in the time axis corresponds to immediately after irradiation). Between before and after the light irradiation, the ITZO film was irradiated with the light obtained by a solar simulator from a side opposed to the glass-substrate (a side where the ITZO film was exposed or a side where the ZSO film was exposed). An exposure time is 10 minutes.

As shown in FIG. 30, in the sample in which the ZSO film is not formed, the electron density of the ITZO film is increased from 2×10 17 cm⁻³ to 2×10 18 cm⁻³ by the exposure of light, and hardly changes even after 6 hours. On the other hand, in the sample in which the ZSO film is formed, the electron concentration of the ITZO film is slightly increased from 1×10 17 cm⁻³ by irradiating with light. However, after 6 hours, the electron concentration almost returned to the original concentration. It is presumed that this phenomenon is one of the factors why the negative shift of the thresholds due to the NBIS rarely occurs in the case where the passivation layer of the ZSO film is used.

FIG. 31 is a graph showing measurement results of an absorption coefficient. FIG. 31 shows the results of measuring the absorption coefficient by an ultraviolet visible near-infrared spectroscopy on the same sample as in FIG. 30. As shown in FIG. 31, the absorption coefficient is almost the same regardless of the presence or absence of the ZSO film. This is attributed to the fact that the ZSO film is 5 nm, which is very thin, and that the ZSO film has a wide band gap. Therefore, the results shown in FIG. 30 indicate that the main reason is not that the ZSO film inhibits the light irradiated to the ITZO film.

By forming the ZSO film by the DC sputtering, an effect of reducing impurities at the surface of the ITZO film and the interface between the ZSO film and the ITZO film, and an effect of preventing damage caused by the respective processes are produced. As a result, it is presumed that the passivation layer of the ZSO film can improve these effects. The DC sputtering in an oxygen-containing atmosphere also reduces the carbon residual components described above. Therefore, it is also expected to omit the heat treatment and the UV ozone treatment for reducing the carbon residual components, or to replace the heat treatment and the UV ozone treatment with a simple treatment (low temperature, low illumination, or shortened treatment times).

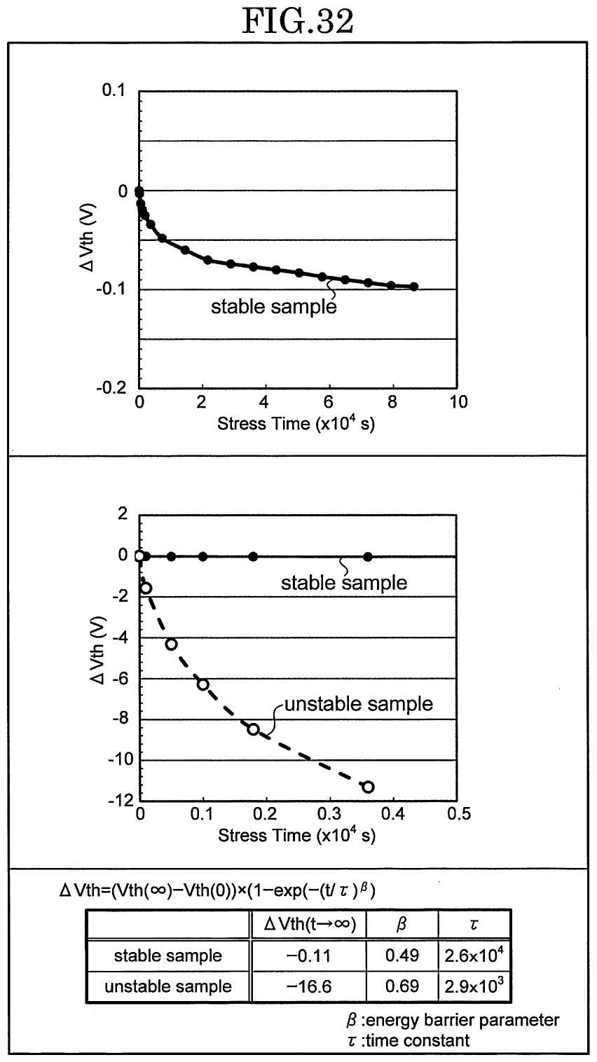

FIG. 32 is a graph showing measurement results of a variation of a threshold shift over time due to the NBS (Negative Bias Stress) and the model formula. The NBS is controlled and maintained so that the voltage of the gate electrode with respect to the source electrode and the drain electrode becomes “Vth−20 V”. The period of time during which the NBS is applied is at most 3600 seconds in the sample (unstable sample), in which the passivation layer of ZSO film is not used, without the treatment of reducing the carbon residual component (lower figure) described above, and is at most 86400 seconds in the sample (stable sample), in which the passivation layer of the ZSO film is further formed, with the treatment of reducing the carbon residual component (upper figure).

FIG. 32 shows the parameters in the case where the threshold shift due to the NBS is fitted using an extended exponential (Stretched Exponential Function). Vth (0) is the initial threshold voltage. τ is a time constant and β is an energy barrier parameter. τ and β differ greatly depending on whether or not the carbon residual components are desorbed and the passivation layers of the ZSO film are formed. Since β reflects the distribution of energy barriers, it is believed that β is different if a mechanism of charge transfer is different. It is also known that β greatly differs depending on a type of gas introduced in a gas sensor using ZnO. In a TFT of stable In₂O₃ with high mobility, the possibility that β differs by the difference of a Fermi level is also shown. Furthermore, as shown in FIG. 32, it was confirmed that ΔVth(t→∞) is two orders of magnitude different between the two samples.

[For ITZO of Different Composition]

In the embodiment described above, although the composition ratio In:Sn:Zn of the target is 20:40:40 (at %), it is not limited to this composition ratio. The measurement results of a threshold shifts due to the NBTS, the PBTS and the NBIS are explained when the composition ratio of the sample is 40:40:20 (at %).

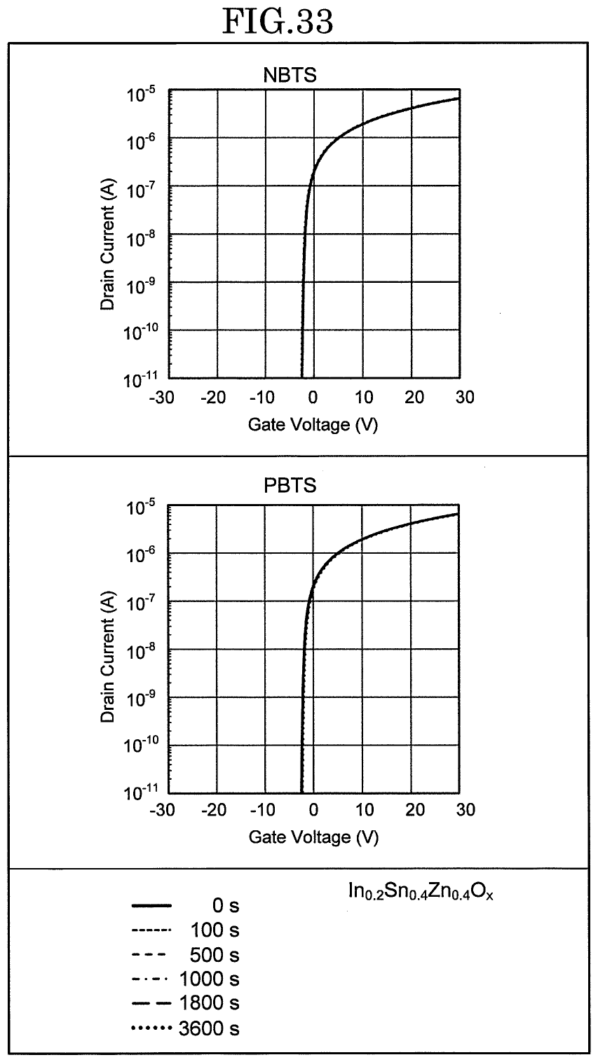

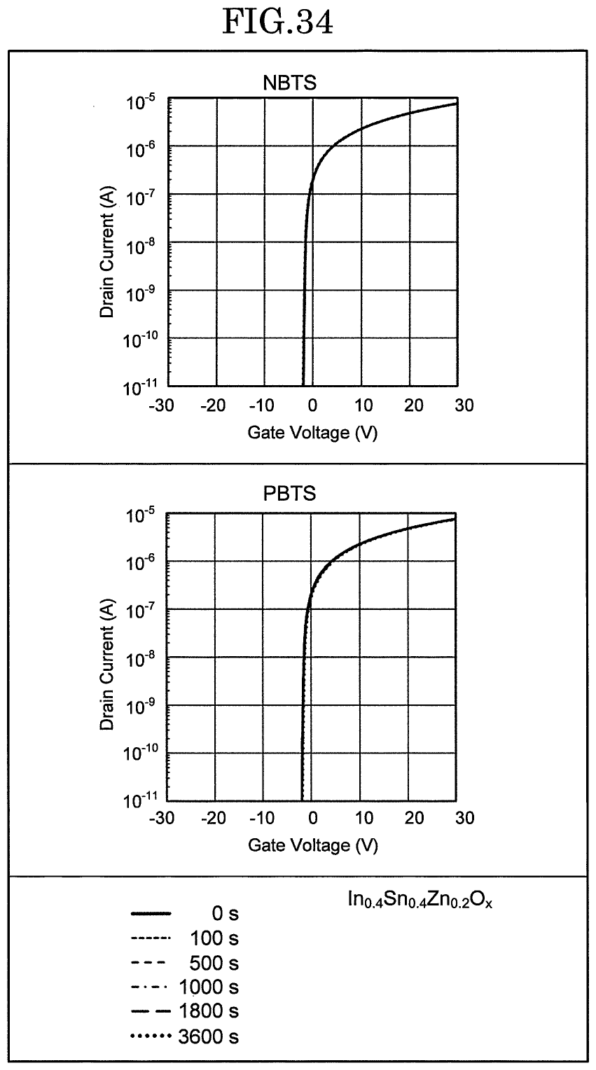

FIG. 33 and FIG. 34 are graphs showing measurement results of a threshold shift due to the NBTS and the PBTS. FIG. 33 is a graph showing the composition ratio In:Sn:Zn of the target is 20:40:40 (at %). FIG. 34 is a graph showing the composition ratio In:Sn:Zn of the target is 40:40:20 (at %). The samples used in the measurements of FIG. 33 and FIG. 34 are all treated to reduce the carbon residual components, and passivation layers of the ZSO film are formed. There is little threshold shift in the composition ratio of any target. Further, the measurement results shown in FIG. 33 are generally similar to the measurement results obtained in the case where the process of reducing the carbon residual components is performed and the passivation layers of the ZSO film are not formed (FIG. 21). That is, an adverse effect on the NBTS and the PBTS by the presence of the ZSO film is not confirmed.

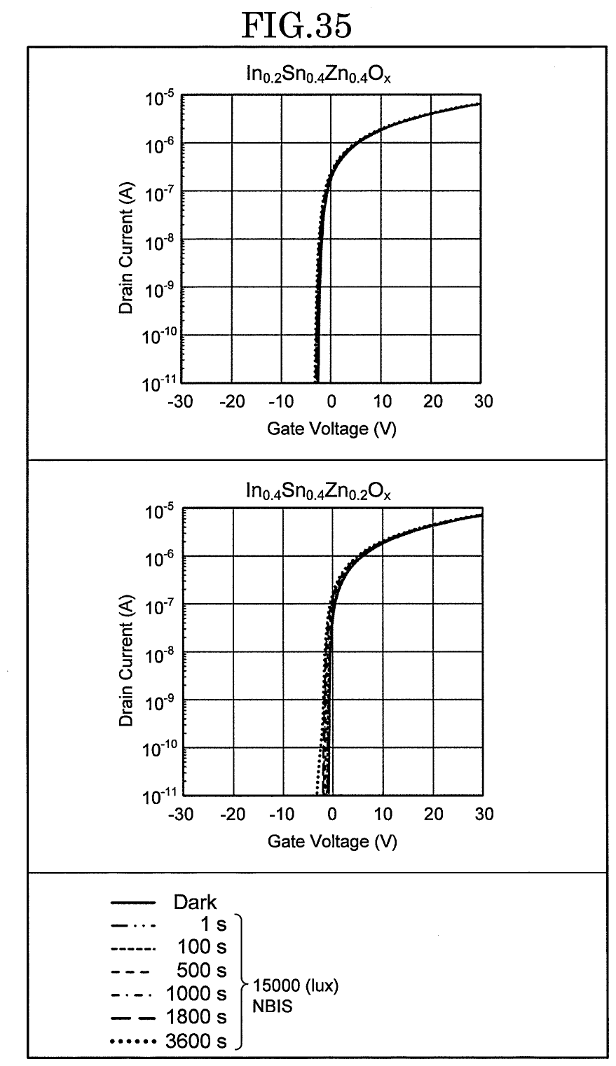

FIG. 35 is a graph showing measurement results of a threshold shift due to the NBIS. In FIG. 35, the measurement results due to the NBIS are compared by two ITZO that differ in the composition ratio of the targets. A field-effect mobility of the sample (In_{0.4}Sn_{0.4}Zn_{0.2}Oₓ) of which the composition ratio In:Sn:Zn of the target is 40:40:20 (at %) is 70 cm²/Vs. A field-effect mobility of the sample (In_{0.2}Sn_{0.4}Zn_{0.4}Oₓ) of which the composition ratio In:Sn:Zn of the target is 20:40:40 (at %) is 50 cm²/Vs.

Although in the case where the composition ratio of the targets is In_{0.4}Sn_{0.4}Zn_{0.2}Oₓ, the negative shift of the thresholds is slightly larger because the mobility is higher than in the case where the composition ratio is In_{0.2}Sn_{0.4}Zn_{0.4}Oₓ, there is no large difference. As described above, even in ITZO other than a particular composition ratio, reducing effects to the threshold shift in various voltage stresses can be obtained by the same method. According to ITZO in which the mobility is at least equal to or lower than 70 cm²/Vs, it has been confirmed that the threshold shift in the voltage stress is sufficiently reduced.

For example, the amount of the threshold shift having a sufficient reducing effect is preferably 3 V or less, and more preferably 1 V or less. If such a reducing effect is obtained, ITZO having a higher mobility can also be applied to the thin film transistor.

[Thin Film Transistor Using Metal Oxide Semiconductor Other than ITZO]

It has been found that the threshold shift due to the voltage stress in the thin film transistor including an ITZO film as the semiconductor described in detail above can be reduced by the reduction process of carbon residual components in ITGO (In—Sn—Ga oxide) and IZO (In—Zn oxide), in addition to ITZO. Therefore, the knowledge on the effectiveness of reducing carbon residual components described above can be generally applied to a thin film transistor containing a metal oxide semiconductor containing In as a channel. It can be said that the knowledge of the passivation layer can be generally applied to the thin film transistor containing the metal oxide semiconductor containing In as the channel by using a passivation layer having an electron affinity smaller and ionization potential larger than those of the semiconductor layer. As described above, the present invention can be particularly suitably applied to a thin film transistor using a metal oxide semiconductor having a high field-effect mobility. This high field-effect mobility is preferably 20 cm²/Vs or more, particularly preferably 40 cm²/Vs or more.

Effects of the UV ozone treatment on the threshold shift due to the NBS in the case where the ITGO film or the IZO film is applied to the semiconducting layers are explained.

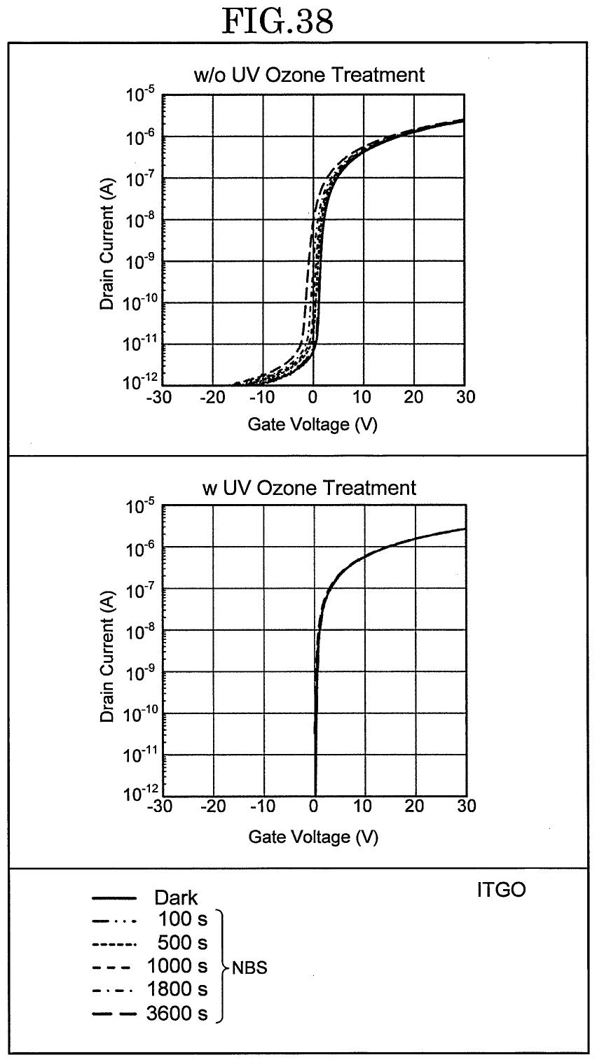

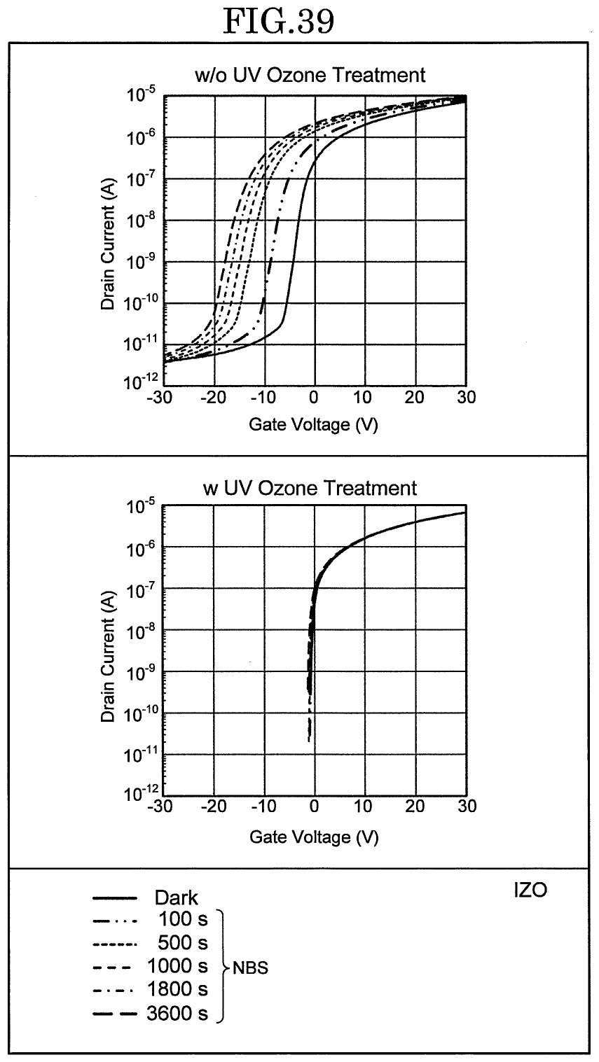

FIG. 38 and FIG. 39 are graphs showing thresholds shifting due to the NBS in the presence or absence of the UV ozone treatment. FIG. 38 is a graph showing the results obtained in the case where the ITGO film is applied to the semiconductor layers (in the case where the composition ratio In:Sn:Ga of the target is 40:20:40 (at %).) FIG. 39 is a graph showing the results obtained in the case where the IZO film is applied to the semiconductor layers (in the case where the composition ratio In:Zn of the target is 50:50 (at %).) In the thin film transistor for threshold measurement, a structure of the sample and measurement conditions are the same as those obtained by the measurement results shown in FIG. 21. As shown in FIG. 38 and FIG. 39, even if the ITGO film or the IZO film is applied to the semiconductor layers, the amount of the threshold shift due to the NBS is sufficiently reduced.

According to the embodiment described above, it is possible to effectively reduce the threshold shift due to the voltage stress occurring in the thin film transistor including the metal oxide semiconductor layers containing In. In addition, according to the embodiment described above, it is possible to effectively reduce the threshold shift due to the NBTS occurring in the thin film transistor including ITZO.

The thin film transistor described above may have the following features.

In an embodiment, a thin film transistor is formed on a substrate, the thin film transistor includes a channel formed by at least part of a metal oxide semiconductor layer containing at least indium (In), a gate electrode, a gate insulating layer arranged between the channel and the gate electrode, a source electrode connected to the metal oxide semiconductor layer, and a drain electrode connected to the metal oxide semiconductor layer. The average concentration of carbon atoms in an area from a surface to the depth of 5 nm of the channel is 1.5×10²¹ cm⁻³ or less. The average concentration of carbon atoms in the area may be 3.5×10²⁰ cm⁻³ or less.

In an embodiment, a thin film transistor is formed on a substrate, the thin film transistor includes a channel formed by at least part of a metal oxide semiconductor layer containing at least indium (In), a gate electrode, a gate insulating layer arranged between the channel and the gate electrode, a source electrode connected to the metal oxide semiconductor layer, and a drain electrode connected to the metal oxide semiconductor layer. The maximum concentration of carbon atoms in an area from a surface to the depth of 5 nm of the channel is 19 at % or less. The maximum concentration may be 8 at % or less.

The gate electrode may be arranged between the substrate and the channel.

The source electrode and the drain electrode may contain a conductive material having oxidation resistance.

The channel may be arranged between the substrate and the gate electrode.

In the metal oxide semiconductor layer, a part of the surface covered with the source electrode and a part of the surface covered with the drain electrode may have a higher concentration of carbon atoms than the surface of the channel.

The amount of a threshold shift may be 0.5 V or less in the case where it is maintained for 3600 seconds that a voltage of the gate electrode with respect to the source electrode and the drain electrode is controlled to be Vth−20 V in a temperature of 60° C. and a dark state.

The metal oxide semiconductor layer may further contain tin (Sn) and zinc (Zn).

An insulating passivation layer covering the channel may be further included. The passivation layer may be a metal oxide layer containing Zn and Si.

In an embodiment, a thin film transistor is formed on a substrate, the thin film transistor includes a channel formed by at least part of a metal oxide semiconductor layer containing at least indium (In), a gate electrode, a gate insulating layer arranged between the channel and the gate electrode, a source electrode connected to the metal oxide semiconductor layer, a drain electrode connected to the metal oxide semiconductor layer, and a passivation layer covering the channel and having an insulating property. The electron affinity of the passivation layer is less than the electron affinity of the metal oxide semiconductor layer.

The electron affinity of the passivation layers may be in a range of 2.0 eV or more and 4.0 eV or less. The ionization potential of the passivation layer may be in a range of 6.0 eV or more and 8.5 eV or less.

The passivation layer may contain amorphous material.

The metal oxide semiconductor layer may further contain tin (Sn) and zinc (Zn).

In an embodiment, a display device includes a plurality of pixel circuits, and each of the plurality of pixel circuits includes the thin film transistor described above.

A plurality of light emitting elements may be included. The plurality of pixel circuits may control light emission by the plurality of light emitting elements.

In an embodiment, an electronic appliance includes the display device described above and a control device that controls the display device.

In an embodiment, a method of manufacturing a thin film transistor includes forming a thin film transistor on a substrate, heating the thin film transistor to 350° C. or higher in atmosphere containing oxygen while a channel is exposed, and forming an insulating layer covering the channel after the heating and before a material containing carbon atoms contacts an exposed portion of the channel. The thin film transistor includes the channel formed by at least part of a metal oxide semiconductor layer containing at least indium (In), a gate electrode, a gate insulating layer arranged between the channel and the gate electrode, a source electrode connected to the metal oxide semiconductor layer on a substrate, and a drain electrode connected to the metal oxide semiconductor layer.

In an embodiment, a method of manufacturing a thin film transistor includes forming a thin film transistor on a substrate, irradiating ultraviolet light in an oxygen-containing atmosphere while a channel is exposed, and forming an insulating layer covering the channel after the irradiating process and before a material containing carbon atoms contacts an exposed portion of the channel. The thin film transistor includes the channel formed by at least part of a metal oxide semiconductor layer containing at least indium (In), a gate electrode, a gate insulating layer arranged between the channel and the gate electrode, a source electrode connected to the metal oxide semiconductor layer, and a drain electrode connected to the metal oxide semiconductor layer.

In an embodiment, a method of manufacturing a thin film transistor includes forming a thin film transistor on a substrate and forming an insulating layer covering a channel by a DC sputtering in an oxygen-containing atmosphere while a channel is exposed. The thin film transistor includes the channel formed by at least part of a metal oxide semiconductor layer containing at least indium (In), a gate electrode, a gate insulating layer arranged between the channel and the gate electrode, a source electrode connected to the metal oxide semiconductor layer, and a drain electrode connected to the metal oxide semiconductor layer.

A target used in the DC sputtering may be a metal oxide having conductivity.

The metal oxide semiconductor layer may be formed by the PVD method.

The average concentration of carbon atoms in an area from a surface to the depth of 5 nm of the exposed portion of the channels prior to the insulating layer being formed may be 1.5×10²¹ cm⁻³ or less after the insulating layer is formed. The average concentration may be 3.5×10²⁰ cm⁻³ or less after the insulating layer is formed.

The maximum concentration of carbon atoms in an area from a surface to the depth of 5 nm of the exposed portion of the channels prior to the insulating layer being formed may be 19 at % or less after the insulating layer is formed. The maximum concentration may be 8 at % or less after the insulating layer is formed.

The gate electrode may be arranged between the substrate and the channel. After the source electrode and the drain electrode are formed, at least part of the carbon atoms present on the surface of the channel may be desorbed.

The channel may be arranged between the substrate and the gate electrode. The insulating layer protecting from carbon atoms may be the gate insulating layer. Before the source electrode and the drain electrode are formed, at least part of the carbon atoms present on the surface of the channel may be desorbed.

The metal oxide semiconductor layer may further contain tin (Sn) and zinc (Zn).

The insulating layer may be a metallic oxide layer containing Zn and Si.

In an embodiment, a method of manufacturing a thin film transistor includes forming a thin film transistor on a substrate, the thin film transistor including a channel formed by at least part of a metal oxide semiconductor layer containing at least indium (In), a gate electrode, a gate insulating layer arranged between the channel and the gate electrode, a source electrode connected to the metal oxide semiconductor layer, a drain electrode connected to the metal oxide semiconductor layer, and a passivation layer having an insulating property and covering the channel. The electron affinity of the passivation layer is smaller than the electron affinity of the metal oxide semiconductor layer.

The electron affinity of the passivation layers may be in a range of 2.0 eV or more and 4.0 eV or less. The ionization potential of the passivation layer may be in a range of 6.0 eV or more and 8.5 eV or less.

The passivation layer may contain amorphous material.

The metal oxide semiconductor layer may further contain tin (Sn) and zinc (Zn).

A thin film transistor formed on a substrate, including:
a channel formed by at least part of a metal oxide semiconductor layer containing at least indium (In), tin (Sn) and zinc (Zn);
a gate electrode;
a gate insulating layer arranged between the channel and the gate electrode;
a source electrode connected to the metal oxide semiconductor layer;
a drain electrode connected to the metal oxide semiconductor layer; and
an insulating layer covering the channel,
wherein
   a length of the channel is 100 μm or less,
   respective thresholds due to NBTS, PBTS and NBIS are 3 V or less,
   NBTS: dark state, temperature “60° C.”, voltage of the gate electrode with respect to the source electrode and the drain electrode “Vth−20 V”, and stress application time “3600 seconds”,
   PBTS: dark state, temperature “60° C.”, voltage of the gate electrode with respect to the source electrode and the drain electrode “Vth+20 V”, and stress application time “3600 seconds”,
   NBIS: light-irradiation condition “15000 Lux”, voltage of the gate electrode with respect to the source electrode and the drain electrode “Vth−V”, and stress application time “3600 seconds”,
   Threshold voltage measurement: voltage of the drain electrode relative to the source electrode “0.1 V”.

The channel may have a ratio of Sn to the sum of In and Sn and Zn of 30 (at %) or more. The channel may have a ratio of Sn to the sum of In and Sn and Zn of 40 (at %) or more.

The channel may have a field-effect mobility of 40 cm²/Vs or more. The channel may have a field-effect mobility of 60 cm²/Vs or more.

The insulating layer may be a metal oxide layer containing Zn and Si.

A length of the channel may be 50 μm or less. The length of the channel may be 20 μm or less.

The amount of the threshold shift due to the NBTS may be 1 V or less.

The amount of the threshold shift due to PBTS may be 1 V or less.

The amount of the threshold shift due to NBIS may be 1 V or less.

### REFERENCES SIGNS LIST

1: first substrate, 2: second substrate, 10: first supporting substrate, 100, 100A, 100B, 100C, 100D, 100E: thin film transistor, 110: base insulating layer, 120, 120B, 125: gate electrode, 130, 135: gate insulating layer, 150, 150B, 155: semiconductor layer, 150a: upper surface, 150b, 150Bb, 155b: backchannel-side surface, 150d: drain surface, 150e, 150eE: etch-stop layer, 151B: source area, 152B: drain area, 155f: ITZO film, 150g, 150Bg, 155g: gate-side surface, 150s: source surface, 160, 160D: passivation layer, 171, 171B, 176: source electrode, 172, 172B, 177: drain electrode, 175f: gold film, 200: interlayer insulating layer, 300: pixel electrode, 400: bank layer, 500: light emitting layer, 600: counter electrode, 900: sealing layer, 1000: display device, 1500: housing, 1600: control device, 1700: storage device, 2000: electronic appliance.

What is claimed is:

1. A thin film transistor formed on a substrate, the thin film transistor comprising:
a channel formed by at least part of a metal oxide semiconductor layer containing Indium (In), a field-effect mobility of the channel being 20 cm²/Vs or more;
a gate electrode arranged between the substrate and the channel;
a gate insulating layer arranged between the channel and the gate electrode;
a source electrode connected to the metal oxide semiconductor layer; and
a drain electrode connected to the metal oxide semiconductor layer, wherein
an average concentration of carbon atoms in an area from a surface to the depth of 5 nm of the channel is 1.5×10²¹ cm⁻³ or less.

2. The thin film transistor according to claim 1, wherein
the metal oxide semiconductor layer further contains tin (Sn) and zinc (Zn).

3. The thin film transistor according to claim 1, wherein
in the metal oxide semiconductor layer, a part of the surface covered with the source electrode and a part of the surface covered with the drain electrode have a higher concentration of carbon atoms than the surface of the channel.

4. The thin film transistor according to claim 1, wherein
the source electrode and the drain electrode contain conductive materials having oxidation resistance.

5. A thin film transistor formed on a substrate, the thin film transistor comprising:
a gate electrode;
a channel formed by at least part of a metal oxide semiconductor layer containing Indium (In), the channel arranged between the substrate and the gate electrode, a field-effect mobility of the channel being 20 cm²/Vs or more;
a gate insulating layer arranged between the channel and the gate electrode;
a source electrode connected to the metal oxide semiconductor layer; and
a drain electrode connected to the metal oxide semiconductor layer,
wherein
an average concentration of carbon atoms in an area from a surface to the depth of 5 nm of the channel is 1.5×10²¹ cm⁻³ or less.

6. The thin film transistor according to claim 5, wherein
the metal oxide semiconductor layer further contains tin (Sn) and zinc (Zn).

7. The thin film transistor according to claim 1, wherein
an amount of a threshold shift is 0.5 V or less in the case where it is maintained for 3600 seconds that a voltage of the gate electrode with respect to the source electrode and the drain electrode is controlled to be Vth−20 V in a temperature of 60° C. and a dark state.

8. The thin film transistor according to claim 1, the thin film transistor further comprising a passivation layer covering the channel and having an insulation property,
wherein
the electron affinity of the passivation layer is less than the electron affinity of the metal oxide semiconductor layer.

9. The thin film transistor according to claim 1, the thin film transistor further comprising a passivation layer covering the channel and having an insulation property,
wherein
the passivation layer is a metal oxide layer containing zinc (Zn) and silicon

10. The thin film transistor according to claim 9, wherein
the metal oxide semiconductor layer further contains tin (Sn) and zinc (Zn).

11. A thin film transistor formed on a substrate, the thin film transistor comprising:
a channel formed by at least part of a metal oxide semiconductor layer containing Indium (In), a field-effect mobility of the channel being 20 cm²/Vs or more;
a gate electrode;
a gate insulating layer arranged between the channel and the gate electrode;
a source electrode connected to the metal oxide semiconductor layer;
a drain electrode connected to the metal oxide semiconductor; and
a passivation layer covering the channel and having an insulation property,
wherein the electron affinity of the passivation layer is less than the electron affinity of the metal oxide semiconductor layer.

12. The thin film transistor according to claim 11, wherein
the metal oxide semiconductor layer further contains tin (Sn) and zinc (Zn).

13. The thin film transistor according to claim 11, wherein
the passivation layer is a metal oxide layer containing zinc (Zn) and silicon (Si).

14. A display device including a plurality of pixel circuits, wherein
each of the plurality of pixel circuits includes the thin film transistor according to claim 1.

15. A method for manufacturing the thin film transistor according to claim 1 on a substrate, the method comprising:
heating the metal oxide semiconductor layer to 350° C. or higher in an atmosphere containing oxygen while the channel is exposed to the atmosphere; and
forming an insulating layer covering the channel after the heating and before a material containing carbon atoms contacts the exposed portion of the channel.

16. The method according to claim 15, wherein
the metal oxide semiconductor layer further contains tin (Sn) and zinc (Zn).

17. The method according to claim 15, wherein
the insulating layer is a metal oxide layer containing zinc (Zn) and silicon (Si).

18. A method for manufacturing the thin film transistor according to claim 1 on a substrate, the method comprising:
irradiating ultraviolet light in an atmosphere containing oxygen while the channel is exposed; and
forming an insulating layer covering the exposed channel after the irradiating process and before a material containing carbon atoms contacts the exposed portion of the channel.

19. A method for manufacturing the thin film transistor according to claim 1 on a substrate, the method comprising:
forming an insulating layer covering the channel by a DC sputtering method in an atmosphere containing oxygen with the channel exposed.

20. The method according to claim 19, wherein
a target used in the DC sputtering method is a conductive metal oxide.

21. The method according to claim 15, the method further comprising:
desorbing at least part of the carbon atoms on the surface of the channel after forming the source electrode and the drain electrode.
